(19) United States
(12) Patent Application Publication
(10) Pub. No.: US 2024/0096416 A1
(43) Pub. Date: Mar. 21, 2024

(54) SEMICONDUCTOR MEMORY DEVICE

(71) Applicant: Kioxia Corporation, Tokyo (JP)

(72) Inventors: Kohei DATE, Yokkaichi (JP); Keisuke SUDA, Yokkaichi (JP)

(73) Assignee: Kioxia Corporation, Tokyo (JP)

(21) Appl. No.: 18/335,680

(22) Filed: Jun. 15, 2023

(30) Foreign Application Priority Data
Sep. 9, 2022 (JP) 2022-143815

(51) Int. Cl. G11C 16/04; H01L 23/528; H10B 41/10; H10B 41/27; H10B 41/35; H10B 43/10; H10B 43/27; H10B 43/35

(52) U.S. Cl. CPC G11C 16/0483; H01L 23/5283; H10B 41/10; H10B 41/27; H10B 41/35; H10B 43/10; H10B 43/27; H10B 43/35

(57) ABSTRACT

According to one embodiment, a semiconductor memory device includes: stacked interconnects including a first interconnect layer and a second interconnect layer, the first interconnect layer including a first area and a second area arranged in a first direction, the second interconnect layer being arranged above the first interconnect layer in a second direction intersecting the first direction, the second interconnect layer not including the first area and including the second area; a first memory pillar arranged in the first area and passing through the first interconnect layer in the second direction; and a second memory pillar arranged in the second area and passing through the first interconnect layer and the second interconnect layer in the second direction.

### CROSS-REFERENCE TO RELATED APPLICATIONS

This application is based upon and claims the benefit of priority from Japanese Patent Application No. 2022-143815, filed Sep. 9, 2022, the entire contents of which are incorporated herein by reference.

### FIELD

Embodiments described herein relate generally to a semiconductor memory device.

### BACKGROUND

A NAND flash memory is known as a semiconductor memory device capable of storing data in a nonvolatile manner. A semiconductor memory device such as a NAND flash memory may adopt a three-dimensional memory structure for higher integration and higher capacity.

### BRIEF DESCRIPTION OF THE DRAWINGS

FIG. 1 is a block diagram showing an example of a configuration of a memory system including a semiconductor memory device according to an embodiment.

FIG. 2 is a circuit diagram showing an example of a circuit configuration of a memory cell array included in the semiconductor memory device according to the embodiment.

FIG. 3 is a plan view showing an example of a planar structure of the memory cell array included in the semiconductor memory device according to the embodiment.

FIG. 4 is a cross-sectional view showing an example of a cross-sectional structure in a memory area of the memory cell array included in the semiconductor memory device according to the embodiment.

FIG. 5 is a cross-sectional view showing an example of a cross-sectional structure of a memory pillar in the memory area of the semiconductor memory device according to the embodiment.

FIG. 6 is a view showing an example of a threshold voltage of each select transistor in each string unit of the memory cell array included in the semiconductor memory device according to the embodiment.

FIG. 7 is a diagram illustrating an example of an operation principle of the semiconductor memory device according to the embodiment.

FIG. 8 is a diagram illustrating another example of the operation principle of the semiconductor memory device according to the embodiment.

FIG. 9 is a diagram illustrating another example of the operation principle of the semiconductor memory device according to the embodiment.

FIG. 10 is a diagram illustrating another example of the operation principle of the semiconductor memory device according to the embodiment.

FIG. 11 is a diagram illustrating another example of the operation principle of the semiconductor memory device according to the embodiment.

FIG. 12 is a flowchart showing an example of a method of manufacturing the memory area of the semiconductor memory device according to the embodiment.

FIG. 13 is a cross-sectional view showing an example of a cross-sectional structure during a process of manufacturing the memory area of the semiconductor memory device according to the embodiment.

FIG. 14 is a partially enlarged view of the cross-sectional structure during the process of manufacturing the memory area of the semiconductor memory device according to the embodiment.

FIG. 15 is a cross-sectional view showing an example of a cross-sectional structure during the process of manufacturing the memory area of the semiconductor memory device according to the embodiment.

FIG. 16 is a cross-sectional view showing an example of a cross-sectional structure during the process of manufacturing the memory area of the semiconductor memory device according to the embodiment.

FIG. 17 is a cross-sectional view showing an example of a cross-sectional structure during the process of manufacturing the memory area of the semiconductor memory device according to the embodiment.

FIG. 18 is a cross-sectional view showing an example of a cross-sectional structure during the process of manufacturing the memory area of the semiconductor memory device according to the embodiment.

FIG. 19 is a cross-sectional view showing an example of a cross-sectional structure during the process of manufacturing the memory area of the semiconductor memory device according to the embodiment.

FIG. 20 is a cross-sectional view showing an example of a cross-sectional structure during the process of manufacturing the memory area of the semiconductor memory device according to the embodiment.

FIG. 21 is a cross-sectional view showing an example of a cross-sectional structure during the process of manufacturing the memory area of the semiconductor memory device according to the embodiment.

FIG. 22 is a cross-sectional view showing an example of a cross-sectional structure during the process of manufacturing the memory area of the semiconductor memory device according to the embodiment.

FIG. 23 is a partially enlarged view of the cross-sectional structure during the process of manufacturing the memory area of the semiconductor memory device according to the embodiment.

FIG. 24 is a partially enlarged view of the cross-sectional structure during the process of manufacturing the memory area of the semiconductor memory device according to the embodiment.

FIG. 25 is a partially enlarged view of the cross-sectional structure during the process of manufacturing the memory area of the semiconductor memory device according to the embodiment.

FIG. 26 is a cross-sectional view showing an example of a cross-sectional structure during the process of manufacturing the memory area of the semiconductor memory device according to the embodiment.

FIG. 27 is a partially enlarged view of the cross-sectional structure during the process of manufacturing the memory area of the semiconductor memory device according to the embodiment.

FIG. 28 is a cross-sectional view showing an example of a cross-sectional structure during the process of manufacturing the memory area of the semiconductor memory device according to the embodiment.

FIG. 29 is a partially enlarged view of the cross-sectional structure during the process of manufacturing the memory area of the semiconductor memory device according to the embodiment.

FIG. 30 is a cross-sectional view showing an example of a cross-sectional structure during the process of manufacturing the memory area of the semiconductor memory device according to the embodiment.

FIG. 31 is a cross-sectional view showing an example of a cross-sectional structure during the process of manufacturing the memory area of the semiconductor memory device according to the embodiment.

FIG. 32 is a cross-sectional view showing an example of a cross-sectional structure during the process of manufacturing the memory area of the semiconductor memory device according to the embodiment.

FIG. 33 is a cross-sectional view showing an example of a cross-sectional structure during the process of manufacturing the memory area of the semiconductor memory device according to the embodiment.

FIG. 34 is a cross-sectional view showing an example of a cross-sectional structure during the process of manufacturing the memory area of the semiconductor memory device according to the embodiment.

FIG. 35 is a partially enlarged view of the cross-sectional structure during the process of manufacturing the memory area of the semiconductor memory device according to the embodiment.

### DETAILED DESCRIPTION

In general, according to one embodiment, a semiconductor memory device includes: stacked interconnects including a first interconnect layer and a second interconnect layer, the first interconnect layer including a first area and a second area arranged in a first direction, the second interconnect layer being arranged above the first interconnect layer in a second direction intersecting the first direction, the second interconnect layer not including the first area and including the second area; a first memory pillar arranged in the first area and passing through the first interconnect layer in the second direction; and a second memory pillar arranged in the second area and passing through the first interconnect layer and the second interconnect layer in the second direction.

Hereinafter, an embodiment will be described with reference to the accompanying drawings. The dimensions and ratios in the drawings are not always the same as the actual ones. In the following description, constituent elements having substantially the same function and configuration will be assigned the same reference symbol. In the case where elements having similar configurations are distinguished from each other in particular, their identical reference symbols may be assigned different letters or numbers.

### 1. Embodiment

### 1.1 Configuration

### 1.1.1 Configuration of Memory System

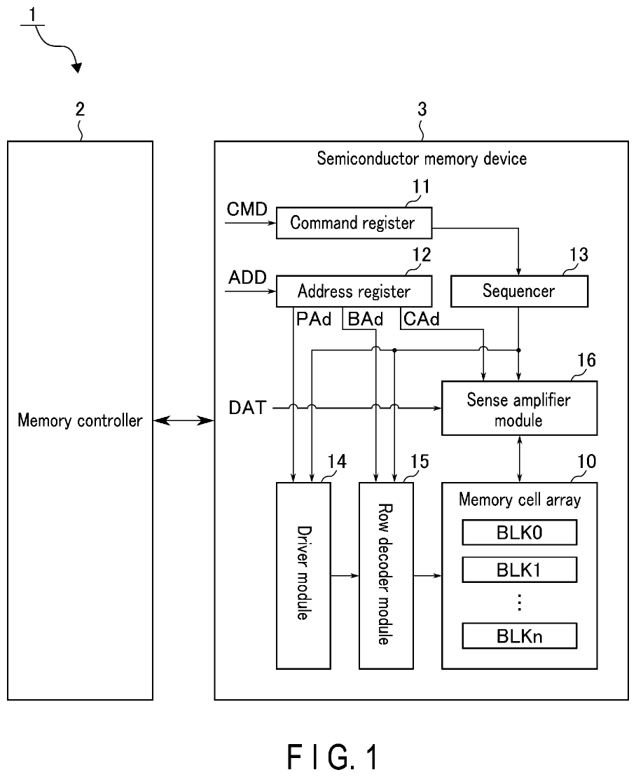

A configuration of a memory system including a semiconductor memory device according to an embodiment will be described with reference to FIG. 1. FIG. 1 is a block diagram showing an example of a configuration of the memory system. The memory system is a memory device configured to be connected to an external host device (not shown). The memory system is, for example, a memory card such as an SD™ card, a universal flash storage (UFS), or a solid-state drive (SSD). The memory system 1 includes a memory controller 2 and a semiconductor memory device 3.

The memory controller 2 is constituted by an integrated circuit such as a system-on-a-chip (SoC), for example. The memory controller 2 controls the semiconductor memory device 3, based on a request received from the host device. Specifically, for example, the memory controller 2 writes data which is requested to be written by the host device to the semiconductor memory device 3. Furthermore, the memory controller 2 reads data which is requested to be read by the host device from the semiconductor memory device 3 and transmits the read data to the host device.

The semiconductor memory device 3 is a memory configured to store data in a nonvolatile manner. The semiconductor memory device 3 is, for example, a NAND flash memory.

### 1.1.2 Configuration of Semiconductor Memory Device

A configuration of the semiconductor memory device 3 will be described by continuously referring to FIG. 1.

The semiconductor memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer equal to or greater than 1). The block BLK is a set of a plurality of memory cell transistors capable of storing data in a nonvolatile manner. The block BLK is used as, for example, a data erase unit. In the memory cell array 10, a plurality of bit lines and a plurality of word lines are provided. Each memory cell transistor is associated with, for example, a single bit line and a single word line. A detailed configuration of the memory cell array 10 will be described later.

The command register 11 is a circuit configured to store commands CMD that the semiconductor memory device 3 receives from the memory controller 2. The command CMD includes, for example, an order to cause the sequencer 13 to execute a read operation, a write operation, an erase operation, etc.

The address register 12 is a circuit configured to store addresses ADD that the semiconductor memory device 3 receives from the memory controller 2. The address ADD includes, for example, a block address BAd, a page address PAd, and a column address CAd. The block address BAd, the page address PAd, and the column address CAd are used to select, for example, a block BLK, a word line, and a bit line, respectively.

The sequencer 13 is a circuit configured to control an operation of another circuit in accordance with a predetermined program. The sequencer 13 controls the overall operation of the semiconductor memory device 3. For example, the sequencer 13 controls the driver module 14, the row decoder module 15, the sense amplifier module 16, etc., based on the command CMD stored in the command register 11. For example, the sequencer 13 executes the read operation, the write operation, the erase operation, etc.

The driver module 14 is a circuit configured to generate a voltage for use in the read operation, the write operation, the erase operation, etc. The driver module 14 applies, for example, based on the page address PAd stored in the address register 12, the generated voltage to a signal line corresponding to the selected word line.

The row decoder module 15 is a circuit configured to select, based on the block address BAd stored in the address register 12, one of the blocks BLK in the memory cell array 10. The row decoder module 15 transfers, for example, the voltage applied to the signal line corresponding to the selected word line to the selected word line in the selected block BLK.

The sense amplifier module 16 selects a bit line based on the column address CAd stored in the address register 12. In the write operation, the sense amplifier module 16 applies, to the selected bit line, a voltage based on the write data DAT received from the memory controller 2. In the read operation, the sense amplifier module 16 determines data stored in a memory cell transistor based on a voltage of the selected bit line. The sense amplifier module 16 transfers the determination result as the read data DAT to the memory controller 2.

### 1.1.3 Circuit Configuration of Memory Cell Array

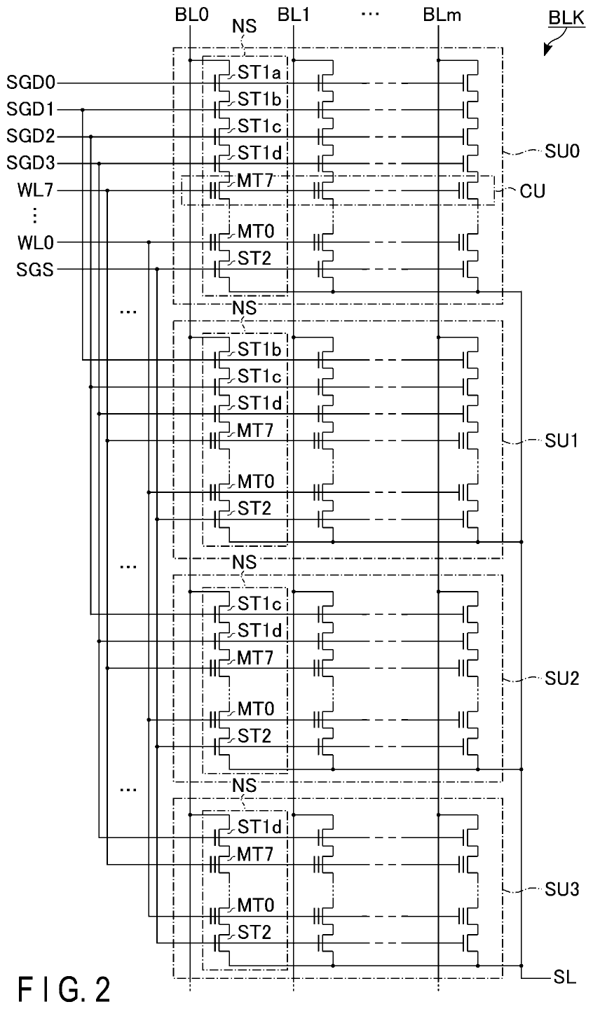

A circuit configuration of the memory cell array 10 will be described with reference to FIG. 2. FIG. 2 is a circuit diagram showing an example of a circuit configuration of the memory cell array 10. FIG. 2 shows one block BLK of the plurality of blocks BLK included in the memory cell array 10. The other blocks BLK have similar configurations to that shown in FIG. 2.

The block BLK includes, for example, four string units SU0 to SU3. The string unit SU is a set of NAND strings NS to be described later. For example, in the write operation or the read operation, NAND strings NS in the string unit SU are collectively selected.

Each string unit SU includes a plurality of NAND strings NS (memory strings) respectively associated with bit lines BL0 to BLm (where m is an integer equal to or greater than 1). Each NAND string NS in the string unit SU0 includes, for example, memory cell transistors MT0 to MT7 and select transistors ST1a to ST1d and ST2. Each NAND string NS in the string unit SU1 includes, for example, memory cell transistors MT0 to MT7 and select transistors ST1b to ST1d and ST2. Each NAND string NS in the string unit SU2 includes, for example, memory cell transistors MT0 to MT7 and select transistors ST1c, ST1d, and ST2. Each NAND string NS in the string unit SU3 includes, for example, memory cell transistors MT0 to MT7 and select transistors ST1d and ST2. The memory cell transistor MT stores data in a nonvolatile manner. The memory cell transistor MT includes a control gate and a charge storage layer. The select transistors ST1a to ST1d and ST2 are switching elements. Each of the select transistors ST1a to ST1d and ST2 is used to select a string unit SU in various operations. In the following, the select transistors ST1a to ST1d will be simply referred to as “select transistors ST1” in the case where they are not distinguished from each other.

In each NAND string NS, the memory cell transistors MT0 to MT7 are coupled in series. A source of the select transistor ST1d is coupled to one end of the memory cell transistors MT0 to MT7 coupled in series. A drain of the select transistor ST2 is coupled to the other end of the memory cell transistors MT0 to MT7 coupled in series. A source of the select transistor ST2 is coupled to a source line SL. In each NAND string NS within the string unit SU0, the select transistors ST1a to ST1d are coupled in series between their associated bit line BL and one end of the coupled memory cell transistors MT0 to MT7. A drain of the select transistor ST1a is coupled to the bit line BL associated therewith. In each NAND string NS within the string unit SU1, the select transistors ST1b to ST1d are coupled in series between their associated bit line BL and one end of the coupled memory cell transistors MT0 to MT7. A drain of the select transistor ST1b is coupled to the bit line BL associated therewith. In each NAND string NS within the string unit SU2, the select transistors ST1c and ST1d are coupled in series between their associated bit line BL and one end of the coupled memory cell transistors MT0 to MT7. A drain of the select transistor ST1c is coupled to the bit line BL associated therewith. In each NAND string NS within the string unit SU3, a drain of the select transistor Slid is coupled to the bit line BL associated therewith. That is, the select transistor Slid in each NAND string NS within the string unit SU3 is coupled between its associated bit line BL and one end of the coupled memory cell transistors MT0 to MT7.

As described above, each NAND string NS is coupled between each associated bit line BL and the source line SL. Out of the memory cell transistors MT0 to MT7, those corresponding to each other among the plurality of NAND strings NS coupled to the same single bit line BL have their gates coupled to a common word line WL.

The control gates of the memory cell transistors MT0 to MT7 in the same block BLK are respectively coupled to the word lines WL0 to WL7. A gate of the select transistor ST1a in the string unit SU0 is coupled to a select gate line SGD0. Gates of the select transistors ST1b in the string units SU0 and SU1 are coupled to a select gate line SGD1. Gates of the select transistors ST1c in the string units SU0 to SU2 are coupled to a select gate line SGD2. Gates of the select transistors Slid in the string units SU0 to SU3 are coupled to a select gate line SGD3. Gates of the select transistors ST2 in the string units SU0 to SU3 are coupled to a select gate line SGS.

Of the select transistors ST1a to Slid in the NAND string NS within the string unit SU0, the select transistor ST1a has a threshold voltage greater than those of the select transistors ST1b to Slid. Of the select transistors ST1b to Slid in the NAND string NS within the string unit SU1, the select transistor ST1b has a threshold voltage greater than those of the select transistors ST1c and Slid. Of the select transistors ST1c and Slid in the NAND string NS within the string unit SU2, the select transistor ST1c has a threshold voltage greater than that of the select transistor ST1d.

The select transistor Slid in the NAND string NS within the string unit SU3 has a threshold voltage greater than that of the select transistor Slid in each NAND string NS within the string units SU0 to SU2. The select transistor ST1c in the NAND string NS within the string unit SU2 has a threshold voltage greater than that of the select transistor ST1c in each NAND string NS within the string units SU0 and SU1. The select transistor ST1b in the NAND string NS within the string unit SU1 has a threshold voltage greater than that of the select transistor ST1b in the NAND string NS within the string unit SU0. The threshold voltage of each select transistor ST1 will be described later in detail.

The bit lines BL0 to BLm are respectively assigned different column addresses CAd. Each bit line BL is shared by the NAND strings NS assigned the same column address CAd among a plurality of blocks BLK. Each of word lines WL0 to WL7 is provided for each block BLK. The source line SL is shared by, for example, the plurality of blocks BLK.

A set of memory cell transistors MT commonly coupled to a word line WL in one string unit SU may be referred to as a cell unit CU, for example. For example, the storage capacity of the cell unit CU including the memory cell transistors MT respectively configured to store 1-bit data is defined as “1-page data”. The cell unit CU may have a storage capacity of 2-page data or more based on the number of bits of data stored in the memory cell transistors MT.

The circuit configuration of the memory cell array 10 is not limited to the configuration described above. For example, the number of string units SU included in each block BLK may be any number. The numbers of memory cell transistors MT, select transistors ST1, and select transistors ST2 included in each NAND string NS may be any number, respectively. For example, the number of select transistors ST1 included in each NAND string NS is one or more and equal to or smaller than the number of string units SU included in each block BLK.

### 1.1.4 Structure of Memory Cell Array

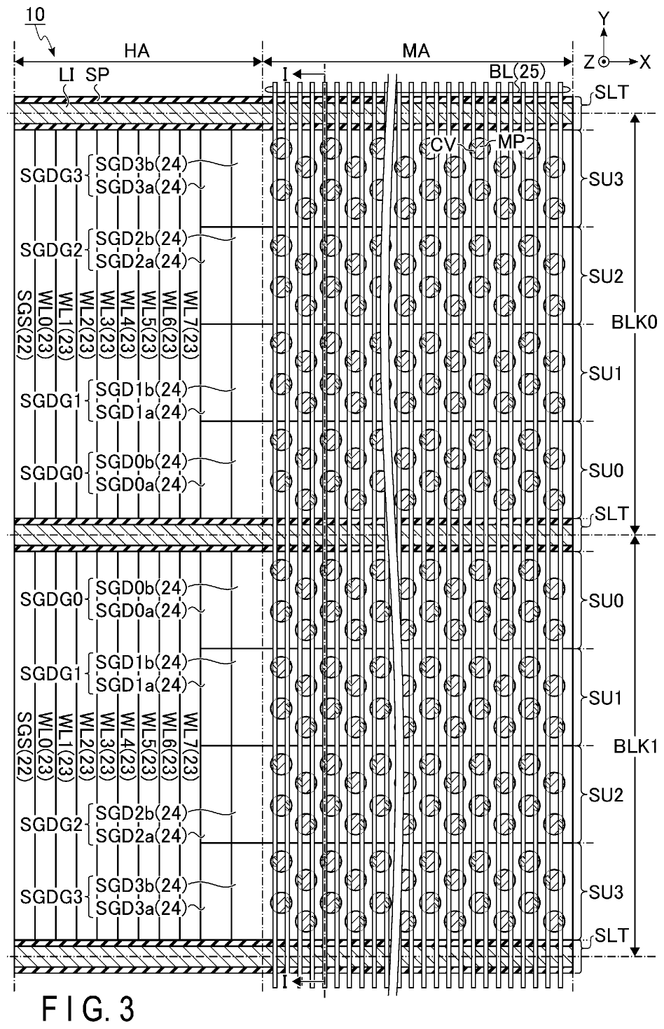

The structure of the memory cell array 10 will be described with reference to FIG. 3 to FIG. 5. In the drawings to be referred to below, an X direction corresponds to the direction in which the word lines WL extend. A Y direction corresponds to the direction in which the bit lines BL extend. A Z direction corresponds to the direction perpendicular to a surface of a semiconductor substrate for use in formation of the semiconductor memory device 3. In the plan views, hatching is added as appropriate to make the views easy to see. The hatching added to the plan views is not necessarily related to the materials or characteristics of the hatched components. In the cross-sectional views, some of the components are omitted as appropriate to make the views easy to see.

### (Planar Structure of Memory Cell Array 10)

FIG. 3 is a plan view showing an example of a planar structure of the memory cell array 10. FIG. 3 shows areas corresponding to two blocks BLK0 and BLK1. The following will describe a case in which the select gate lines SGD0 to SGD3 each have two sets (two layers). The lower select gate line SGD0 (hereinafter referred to as “SGD0a”) in combination with the upper select gate line SGD0 (hereinafter referred to as “SGD0b”) will be referred to as a “select gate line group SGDG0”. The lower select gate line SGD1 (hereinafter referred to as “SGD1a”) in combination with the upper select gate line SGD1 (hereinafter referred to as “SGD1b”) will be referred to as a “select gate line group SGDG1”. The lower select gate line SGD2 (hereinafter referred to as “SGD2a”) in combination with the upper select gate line SGD2 (hereinafter referred to as “SGD2b”) will be referred to as a “select gate line group SGDG2”. The lower select gate line SGD3 (hereinafter referred to as “SGD3a”) in combination with the upper select gate line SGD3 (hereinafter referred to as “SGD3b”) will be referred to as a “select gate line group SGDG3”.

The select gate lines SGD0 to SGD3 may each be one or three or more in number. In the case where the select gate lines SGD0 to SGD3 are each one in number, the select gate line group SGDG0 includes one select gate line SGD0. The select gate line group SGDG1 includes one select gate line SGD1. The select gate line group SGDG2 includes one select gate line SGD2. The select gate line group SGDG3 includes one select gate line SGD3. In the case where the select gate lines SGD0 to SGD3 are each three or more in number, the select gate line group SGDG0 includes three or more select gate lines SGD0. The select gate line group SGDG1 includes three or more select gate lines SGD1. The select gate line group SGDG2 includes three or more select gate lines SGD2. The select gate line group SGDG3 includes three or more select gate lines SGD3.

The memory cell array 10 is divided into a memory area MA and a hookup area HA, for example, in the X direction. The memory area MA is adjacent to the hookup area HA in the X direction. The memory area MA and the hookup area HA include interconnects in which the select gate line SGS, the word lines WL0 to WL7, and the select gate line groups SGDG3 to SGDG0 are stacked with a space therebetween in the Z direction sequentially from a lower layer. Hereinafter, a plurality of interconnect layers 22 to 24 (the select gate line SGS, the word lines WL0 to WL7, and the select gate line groups SGDG0 to SGDG3) in which the select gate line SGS, the word lines WL0 to WL7, and the select gate line groups SGDG3 to SGDG0 are stacked with a space therebetween in the Z direction sequentially from a lower layer will be referred to as “stacked interconnects SI”. The memory area MA is an area including the plurality of NAND strings NS. The hookup area HA is an area for use in coupling between the stacked interconnects SI and the row decoder module 15.

The memory cell array 10 includes a plurality of members SLT.

The plurality of members SLT are each formed into, for example, a line shape extending in the X direction and are arranged side by side in the Y direction. The member SLT crosses the memory area MA and the hookup area HA. In other words, the plurality of members SLT extend in the Z direction and the X direction, and divide the stacked interconnects SI in the Y direction while being spaced apart from each other in the Y direction with the stacked interconnects SI interposed therebetween. One block BLK is arranged between two members SLT adjacent to each other in the Y direction. In other words, the member SLT is provided between two blocks BLK adjacent to each other in the Y direction. The member SLT divides the stacked interconnects SI of two blocks BLK adjacent to each other in the Y direction. FIG. 3 shows the example in which three members SLT arranged in the Y direction are provided. Each of the two blocks BLK0 and BLK1 is arranged between an adjacent two of the three members SLT.

The member SLT includes, for example, a contact plug LI and a spacer SP. The contact plug LI is formed into, for example, a line shape extending in the X direction. The contact plug LI electrically couples, for example, the source line SL to an interconnect provided above the memory cell array 10. The contact plug LI is formed of a conductive material and includes, for example, tungsten. The spacer SP is provided on a side surface of the contact plug LI. In other words, the contact plug LI is surrounded by the spacer SP in a planar view in an XY plane. A contact plug LI is isolated and insulated from the stacked interconnects SI adjacent to the contact plug LI in the Y direction by the spacer SP. The spacer SP is formed of an insulating material and includes, for example, silicon oxide. The member SLT may not include the contact plug LI.

In the memory area MA, the plurality of interconnect layers 24 (the select gate lines groups SGDG0 to SGDG3) respectively have terrace portions. In the memory area MA, the terrace portion of the select gate line group SGDG0 corresponds to the upper surface of the select gate line SGD0b. In the memory area MA, the terrace portion of the select gate line group SGDG1 corresponds to the upper surface of the end portion in the Y direction of the select gate line SGD1b. In the memory area MA, the terrace portion of the select gate line group SGDG2 corresponds to the upper surface of the end portion in the Y direction of the select gate line SGD2b. In the memory area MA, the terrace portion of the select gate line group SGDG3 corresponds to the upper surface of the end portion in the Y direction of the select gate line SGD3b.

Above the terrace portion of the interconnect layer 24 functioning as the select gate line SGD3b, six interconnect layers 24 respectively functioning as the select gate lines SGD0a, SGD0b, SGD1a, SGD1b, SGD2a, and SGD2b are eliminated. Above the terrace portion of the interconnect layer 24 functioning as the select gate line SGD2b, four interconnect layers 24 respectively functioning as the select gate lines SGD0a, SGD0b, SGD1a, and SGD1b are eliminated. Above the terrace portion of the interconnect layer 24 functioning as the select gate line SGD1b, two interconnect layers 24 respectively functioning as the select gate lines SGD0a and SGD0b are eliminated. As described above, the memory area MA has a staircase portion in which the end portions in the Y direction of the plurality of interconnect layers 24 (the select gate line groups SGDG0 to SGDG3) are drawn out in a stepwise manner.

With the structure of the select gate line groups SGDG0 to SGDG3 described above, an area between two members SLT adjacent to each other in the Y direction are divided into an area including the select gate line groups SGDG0 to SGDG3, an area including the select gate line groups SGDG1 to SGDG3 and not including the select gate line group SGDG0, an area including the select gate line groups SGDG2 and SGDG3 and not including the select gate line groups SGDG0 and SGDG1, and an area including the select gate line group SGDG3 and not including the select gate line groups SGDG0 to SGDG2. These areas correspond to the string units SU0 to SU3, respectively.

In each of the blocks BLK0 and BLK1, the string units SU0 to SU3 are arranged in the order of the string unit SU0, the string unit SU1, the string unit SU2, and the string unit SU3 from the side of the member SLT between the block BLK0 and the block BLK1 in the Y direction.

In the memory area MA, the memory cell array 10 includes, for example, a plurality of memory pillars MP, a plurality of contact plugs CV, and a plurality of interconnect layers 25 (bit lines BL).

The memory pillar MP functions as a single NAND string NS. The plurality of memory pillars MP are arranged in, for example, a 16-row staggered pattern in each area between two members SLT adjacent to each other in the Y direction.

The plurality of bit lines BL are each formed into, for example, a line shape extending in the Y direction and are arranged side by side in the X direction. The bit lines BL are arranged in such a manner as to be located above at least one memory pillar MP for each string unit SU. The example in FIG. 3 shows the arrangement in which two bit lines BL are located above one memory pillar MP. Each memory pillar MP is electrically coupled via a contact plug CV to one of the bit lines BL arranged to be located above the memory pillar MP concerned.

In the hookup area HA, the plurality of interconnect layers 22 to 24 (the select gate line SGS, the word lines WL0 to WL7, and the select gate line groups SGDG0 to SGDG3) respectively have terrace portions. In the hookup area HA, the terrace portions of the plurality of interconnect layers 22 to 24 (the select gate line SGS, the word lines WL0 to WL7, and the select gate line groups SGDG0 to SGDG3) correspond to the upper surfaces of the end portions in the X direction of the interconnect layers 22 to 24. Each of these terrace portions is an area provided with a contact plug (not shown) for electrically coupling the plurality of interconnect layers 22 to 24 to an interconnect provided above the memory cell array 10. As described above, the hookup area HA has the staircase portion in which the respective end portions in the X direction of the stacked interconnects SI (the select gate line SGS, the word lines WL0 to WL7, and the select gate line group SGDG0 to SGDG3) are drawn out in a stepwise manner. In the hookup area HA, the stacked interconnects SI may not have the staircase portion.

FIG. 3 shows the example in which two blocks BLK are provided. In the case of the three or more blocks BLK being provided, for example, the structure shown in FIG. 3 is repeatedly arranged in the Y direction.

The planar structure of the memory cell array 10 is not limited to the structure described above. For example, the number of select gate line groups SGDG may be any number based on the number of string units SU.

### (Cross-Sectional Structure in Memory Area MA)

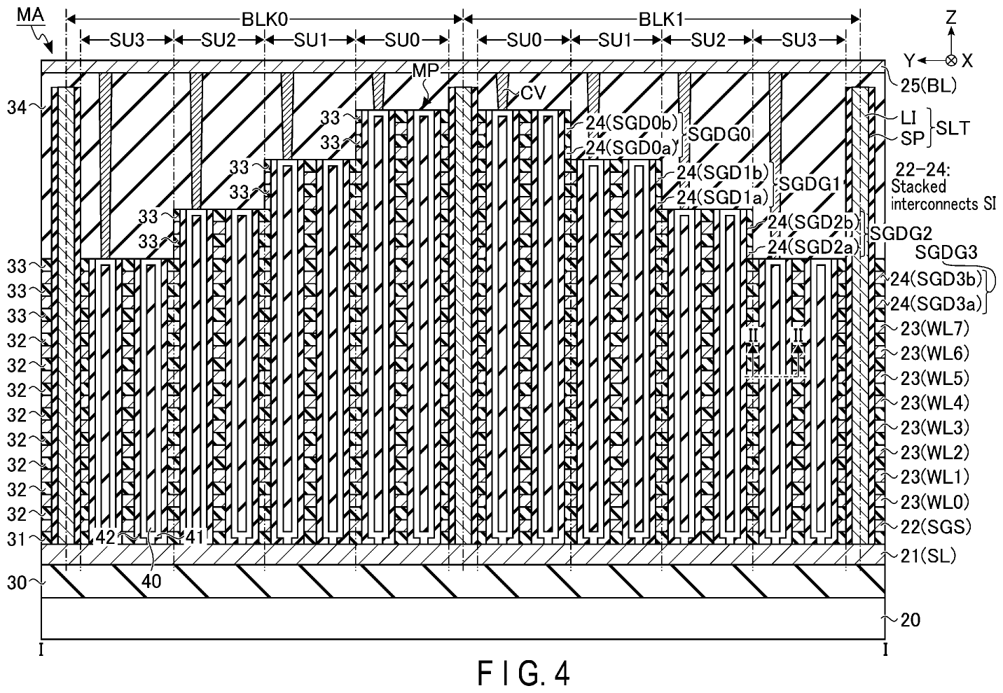

FIG. 4 is a cross-sectional view, taken along line I-I in FIG. 3, showing an example of a cross-sectional structure in the memory area MA of the memory cell array 10.

In the memory area MA, the memory cell array 10 further includes, for example, a semiconductor substrate 20, an interconnect layer 21, and insulating layers 30 to 34.

The insulating layer 30 is provided on the semiconductor substrate 20. The insulating layer 30 includes, for example, a circuit (not shown) corresponding to the row decoder module 15, the sense amplifier module 16, etc. The insulating layer 30 is formed of an insulating material and includes, for example, silicon oxide. The interconnect layer 21 is provided on the insulating layer 30. The interconnect layer 21 is formed into, for example, a plate shape extending along the XY plane, and is used as a source line SL. The interconnect layer 21 is formed of a conductive material and includes, for example, silicon doped with phosphorus.

The insulating layer 31 is provided on the interconnect layer 21. The insulating layer 31 is formed of an insulating material and includes, for example, silicon oxide. The interconnect layer 22 is provided on the insulating layer 31. The interconnect layer 22 is formed into, for example, a plate shape extending along the XY plane. The interconnect layer 22 is used as the select gate line SGS. The interconnect layer 22 is formed of a conductive material and includes, for example, tungsten.

A plurality of insulating layers 32 and the plurality of interconnect layers 23 are alternately stacked one by one on the interconnect layer 22. In other words, the plurality of interconnect layers 23 with a space therebetween in the Z direction are provided above the interconnect layer 22. The interconnect layer 23 is formed into, for example, a plate shape extending along the XY plane. The plurality of interconnect layers 23 are respectively used as the word lines WL0 to WL7, in the order from the side of the semiconductor substrate 20. The insulating layer 32 is formed of an insulating material and includes, for example, silicon oxide. The interconnect layer 23 is formed of a conductive material and includes, for example, tungsten.

A plurality of insulating layers 33 and the plurality of interconnect layers 24 are alternately stacked one by one on the uppermost interconnect layer 23 (that is, the word line WL7). In other words, the plurality of interconnect layers 24 with a space therebetween in the Z direction are provided above the uppermost interconnect layer 23. The interconnect layer 24 is formed into, for example, a plate shape extending along the XY plane. The plurality of interconnect layers 24 are respectively used as the select gate lines SGD3a, SGD3b, SGD2a, SGD2b, SGD1a, SGD1b, SGD0a, and SGD0b in the order from the side of the semiconductor substrate 20. The insulating layer 33 is formed of an insulating material and includes, for example, silicon oxide. The interconnect layer 24 is formed of a conductive material and includes, for example, tungsten.

The example in FIG. 4 shows the case in which the select gate line groups SGDG0 to SGDG3 are formed into a stepwise shape having steps in the Y direction. Specifically, there are two steps in the Y direction between the select gate lines SGD0b and SGD1b. There are two steps in the Y direction between the select gate lines SGD1b and SGD2b. There are two steps in the Y direction between the select gate lines SGD2b and SGD3b. In other words, the terrace portion of the select gate line SGD1b is located two steps below the terrace portion of the select gate line SGD0b in the Y direction. The terrace portion of the select gate line SGD2b is located two steps below the terrace portion of the select gate line SGD1b in the Y direction. The terrace portion of the select gate line SGD3b is located two steps below the terrace portion of the select gate line SGD2b in the Y direction.

Furthermore, the string unit SU0 includes the select gate line groups SGDG0 to SGDG3 (the select gate lines SGD0a, SGD0b, SGD1a, SGD1b, SGD2a, SGD2b, SGD3a, and SGD3b). The string unit SU1 includes the select gate line groups SGDG1 to SGDG3 (the select gate lines SGD1a, SGD1b, SGD2a, SGD2b, SGD3a, and SGD3b) and does not include the select gate line group SGDG0. The string unit SU2 includes the select gate line groups SGDG2 and SGDG3 (the select gate lines SGD2a, SGD2b, SGD3a, and SGD3b) and does not include the select gate line groups SGDG0 and SGDG1. The string unit SU3 includes the select gate line group SGDG3 (the select gate lines SGD3a and SGD3b) and does not include the select gate line groups SGDG0 to SGDG2.

In other words, the select gate lines SGD0a and SGD0b are included in the string unit SU0 and are not included in the string units SU1 to SU3. The select gate lines SGD1a and SGD1b are included in the string units SU0 and SU1 and are not included in the string units SU2 and SU3. The select gate lines SGD2a and SGD2b are included in the string units SU0 to SU2 and are not included in the string unit SU3. The select gate lines SGD3a and SGD3b are included in the string units SU0 to SU3.

The insulating layer 33 is provided on the uppermost interconnect layer 24 within each string unit SU. The insulating layer 34 is provided on the uppermost insulating layer 33 within each string unit SU. The insulating layer 34 is formed of an insulating material and includes, for example, silicon oxide.

The interconnect layer 25 is provided on the insulating layer 34. The interconnect layer 25 is formed into, for example, a line shape extending in the Y direction, and is used as the bit line BL. The interconnect layer 25 is formed of a conductive material and includes, for example, copper.

The memory pillar MP extends in the Z direction. The memory pillar MP penetrates (passes through) the insulating layers 31 to 33 and the interconnect layers 22 to 24. The memory pillar MP is formed into, for example, a cylindrical shape. A lower end of the memory pillar MP is in contact with the interconnect layer 21.

A portion (intersecting portion) in which the memory pillar MP intersects the interconnect layer 22 functions as the select transistor ST2. A portion in which the memory pillar MP intersects the single interconnect layer 23 (the interconnect layer arranged below the interconnect layer 24 in the Z direction) functions as the memory cell transistor MT. In other words, the memory cell transistor MT is formed in a portion in which the memory pillar MP (the semiconductor layer 41 to be described later) intersects the single interconnect layer 23. A portion in which the memory pillar MP intersects two interconnect layers 24 (the select gate line groups SGDG) functions as the select transistor ST1. In other words, the select transistor ST1 is formed in the portion in which the memory pillar MP (the semiconductor layer 41 to be described later) intersects two interconnect layers 24 (the select gate line group SGDG). That is, the select transistor ST1a is formed in the portion in which the memory pillar MP intersects the select gate line groups SGDG0. The select transistor ST1b is formed in the portion in which the memory pillar MP intersects the select gate line group SGDG1. The select transistor ST1c is formed in the portion in which the memory pillar MP intersects the select gate line group SGDG2. The select transistor ST1d is formed in the portion in which the memory pillar MP intersects the select gate line group SGDG3.

The memory pillar MP includes, for example, a core member 40, a semiconductor layer 41, and a stacked film 42.

The core member 40 extends in the Z direction. For example, an upper end of the core member 40 is located above the uppermost interconnect layer 24 within each string unit SU, and a lower end of the core member 40 is located above the interconnect layer 21. The core member 40 is formed of an insulating material and includes, for example, silicon oxide.

The semiconductor layer 41 covers the periphery of the core member 40. In the lower end of the memory pillar MP, the semiconductor layer 41 is partially in contact with the interconnect layer 21. The semiconductor layer 41 penetrates (passes through) the insulating layers 31 to 33 and the interconnect layers 22 to 24 in the Z direction. The semiconductor layer 41 includes, for example, silicon.

The stacked film 42 covers the side and bottom surfaces of the semiconductor layer 41 except for the portion in which the semiconductor layer 41 and the interconnect layer 21 are in contact with each other.

An upper end of the memory pillar MP (the semiconductor layer 41) within the string unit SU0 is located above an upper end of the memory pillar MP (the semiconductor layer 41) within the string unit SU1 in the Z direction. The upper end of the memory pillar MP (the semiconductor layer 41) within the string unit SU1 is located above an upper end of the memory pillar MP (the semiconductor layer 41) within the string unit SU2 in the Z direction. The upper end of the memory pillar MP (the semiconductor layer 41) within the string unit SU2 is located above an upper end of the memory pillar MP (the semiconductor layer 41) within the string unit SU3 in the Z direction.

In other words, the upper end of the memory pillar MP (the semiconductor layer 41) within the string unit SU1 is located between the select gate line SGD1b and the select gate line SGD0a (SGD0b) in the Z direction. The upper end of the memory pillar MP (the semiconductor layer 41) within the string unit SU0 is located above the select gate line SGD0a (SGD0b). The upper end of the memory pillar MP (the semiconductor layer 41) within the string unit SU2 is located between the select gate line SGD2b and the select gate line SGD1a (SGD1b) in the Z direction. The upper end of the memory pillar MP (the semiconductor layer 41) within the string unit SU1 is located above the select gate line SGD1a (SGD1b). The upper end of the memory pillar MP (the semiconductor layer 41) within the string unit SU3 is located between the select gate line SGD3b and the select gate line SGD2a (SGD2b) in the Z direction. The upper end of the memory pillar MP (the semiconductor layer 41) within the string unit SU2 is located above the select gate line SGD2a (SGD2b).

Furthermore, the memory pillar MP arranged in the string unit SU0 penetrates the select gate lines SGD3a, SGD3b, SGD2a, SGD2b, SGD1a, SGD1b, SGD0a, and SGD0b in the Z direction. The memory pillar MP arranged in the string unit SU1 penetrates the select gate lines SGD3a, SGD3b, SGD2a, SGD2b, SGD1a, and SGD1b and does not penetrate the select gate lines SGD0a SGD0b in the Z direction. The memory pillar MP arranged in the string unit SU2 penetrates the select gate lines SGD3a, SGD3b, SGD2a, and SGD2b and does not penetrate the select gate lines SGD1a, SGD1b, SGD0a and SGD0b in the Z direction. The memory pillar MP arranged in the string unit SU3 penetrates the select gate lines SGD3a and SGD3b and does not penetrate the select gate lines SGD2a, SGD2b, SGD1a, SGD1b, SGD0a, and SGD0b in the Z direction.

The select gate line SGD0b is an interconnect layer 24 positioned first from the upper end of the memory pillar MP within the string unit SU0. The select gate line SGD1b is an interconnect layer 24 positioned first from the upper end of the memory pillar MP within the string unit SU1. The select gate line SGD2b is an interconnect layer 24 positioned first from the upper end of the memory pillar MP within the string unit SU2. The select gate line SGD3b is an interconnect layer 24 positioned first from the upper end of the memory pillar MP within the string unit SU3.

A height from the upper end of the memory pillar MP within the string unit SU1 to the select gate line SGD1b is approximately equal to, for example, a height from the upper end of the memory pillar MP within the string unit SU0 to the select gate line SGD0b. The same applies to a height from the upper end of the memory pillar MP within the string unit SU2 to the select gate line SGD2b, and a height from the upper end of the memory pillar MP within the string unit SU3 to the select gate line SGD3b.

The contact plug CV is provided on the semiconductor layer 41. The contact plug CV is formed into, for example, a columnar shape extending in the Z direction. An upper end of the contact plug CV is in contact with the interconnect layer 25. The contact plug CV electrically couples the memory pillar MP (the semiconductor layer 41) to the interconnect layer 25 provided above the memory cell array 10. A length in the Z direction of the contact plug CV is different for each string unit SU. Specifically, a length in the Z direction of the contact plug CV within the string unit SU0 is smaller than that of the contact plug CV within the string unit SU1. The length in the Z direction of the contact plug CV within the string unit SU1 is smaller than that of the contact plug CV within the string unit SU2. The length in the Z direction of the contact plug CV within the string unit SU2 is smaller than that of the contact plug CV within the string unit SU3. In the cross-sectional structure shown in FIG. 4, the plurality of memory pillars MP (the semiconductor layer 41) arranged in the string units SU0 to SU3 are coupled in common to the interconnect layer 25 arranged above the stacked interconnects SI, via the contact plugs CV respectively provided on the memory pillars MP (the semiconductor layer 41). The contact plug CV is formed of a conductive material and includes, for example, tungsten.

The members SLT extend in the Z direction. The member SLT penetrates the insulating layers 31 to 33 and the interconnect layers 22 to 24. A lower end of the member SLT is in contact with the interconnect layer 21. The contact plug LI is provided along the member SLT. An upper end of the contact plug LI is located above the upper end of the memory pillar MP. The upper end of the contact plug LI is not in contact with the interconnect layer 25. A lower end of the contact plug LI is in contact with the interconnect layer 21. The spacer SP covers the periphery of the contact plug LI. The contact plug LI is isolated and insulated from the interconnect layers 22 to 24 by the spacer SP.

With the above structure, the YZ plane of the stacked interconnects SI across two blocks BLK adjacent to each other in the Y direction takes a symmetric shape in which the member SLT provided between these blocks BLK serves the center axis.

### (Cross-Sectional Structure of Memory Pillar MP)

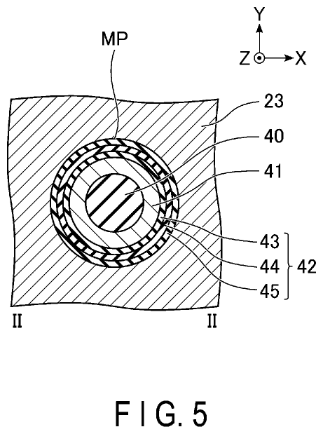

FIG. 5 is a cross-sectional view, taken along line II-II in FIG. 4, showing an example of a cross-sectional structure of the memory pillar MP. Specifically, FIG. 5 shows a cross-sectional structure of the memory pillar MP in a layer that is in parallel to the surface of the semiconductor substrate 20 and includes the interconnect layer 23. As shown in FIG. 5, the stacked film 42 includes a tunnel insulating film 43, an insulating film 44, and a block insulating film 45.

The core member 40 is provided in the central portion of the memory pillar MP. The semiconductor layer 41 covers the periphery of the core member 40. The tunnel insulating film 43 covers the periphery of the semiconductor layer 41. The tunnel insulating film 43 is formed of an insulating material and includes, for example, silicon oxynitride (SiON). The insulating film 44 covers the periphery of the tunnel insulating film 43. The insulating film 44 functions as a charge storage layer of the memory cell transistor MT. The insulating film 44 is formed of an insulating material and includes, for example, silicon nitride. The block insulating film 45 covers the periphery of the insulating film 44. The block insulating film 45 is formed of an insulating material and includes, for example, silicon oxide. The interconnect layer 23 covers the periphery of the block insulating film 45. Meanwhile, a metal oxide such as an aluminum oxide may be further provided between the block insulating film 45 and the interconnect layer 23 in the cross-sectional structure shown in FIG. 5 and around the interconnect layers 22 to 24 as a block insulating film in such a manner as to cover the surface of conductive material of the interconnect layers 22 to 24.

### 1.1.5 Threshold Voltage of Select Transistor

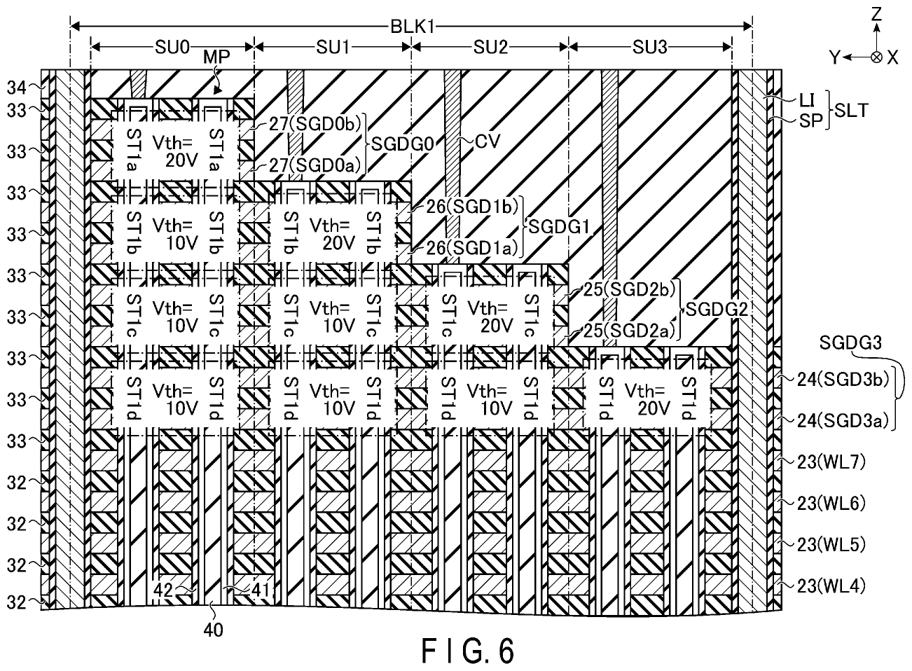

A threshold voltage of the select transistor ST1 will be described with reference to FIG. 6. FIG. 6 is a view showing an example of a threshold voltage of each select transistor ST1 in each string unit SU. FIG. 6 shows an area corresponding to the block BLK1 in the cross-sectional structure shown in FIG. 4. The other blocks BLK each have the select transistors ST1 having threshold voltages which are also set as shown in FIG. 6.

As described above, the select transistor ST1a is formed in the portion in which the select gate line group SGDG0 intersects with the memory pillar MP. The select transistor SIM is formed in the portion in which the select gate line group SGDG1 intersects the memory pillar MP. The select transistor ST1c is formed in the portion in which the select gate line group SGDG2 intersects the memory pillar MP. The select transistor ST1d is formed in the portion in which the select gate line group SGDG3 intersects the memory pillar MP.

In the string unit SU0, an area corresponding to the select gate line group SGDG0 of each memory pillar MP is doped with boron. In other words, the memory pillar MP (the semiconductor layer 41) has an area surrounded by the select gate lines SGD0a and SGD0b and the insulating layer 33 between the select gate lines SGD0a and SGD0b (for example, the semiconductor layer 41 of the memory pillar MP, surrounded by a layer from a lower end of the select gate line SGD0a to an upper end of the select gate line SGD0b), and this area is doped with boron. Therefore, in the string unit SU0, the area corresponding to the select gate line group SGDG0 is greater in boron concentration than an area corresponding to the select gate line group SGDG1, an area corresponding to the select gate line group SGDG2, and an area corresponding to the select gate line group SGDG3.

In the string unit SU1, an area corresponding to the select gate line group SGDG1 of each memory pillar MP is doped with boron. In other words, the memory pillar MP (the semiconductor layer 41) has an area surrounded by the select gate lines SGD1a and SGD1b and the insulating layer 33 between the select gate lines SGD1a and SGD1b (for example, the semiconductor layer 41 of the memory pillar MP, surrounded by a layer from a lower end of the select gate line SGD1a to an upper end of the select gate line SGD1b), and this area is doped with boron. Therefore, in the string unit SU1, the area corresponding to the select gate line group SGDG1 is greater in boron concentration than an area corresponding to the select gate line group SGDG2, and an area corresponding to the select gate line group SGDG3.

In the string unit SU2, an area corresponding to the select gate line group SGDG2 of each memory pillar MP is doped with boron. In other words, the memory pillar MP (the semiconductor layer 41) has an area surrounded by the select gate lines SGD2a and SGD2b and the insulating layer 33 between the select gate lines SGD2a and SGD2b (for example, the semiconductor layer 41 of the memory pillar MP, surrounded by a layer from a lower end of the select gate line SGD2a to an upper end of the select gate line SGD2b), and this area is doped with boron. Therefore, in the string unit SU2, the area corresponding to the select gate line group SGDG2 is greater in boron concentration than an area corresponding to the select gate line group SGDG3.

In the string unit SU3, an area corresponding to the select gate line group SGDG3 of each memory pillar MP is doped with boron. In other words, the memory pillar MP (the semiconductor layer 41) has an area surrounded by the select gate lines SGD3a and SGD3b and the insulating layer 33 between the select gate lines SGD3a and SGD3b (for example, the semiconductor layer 41 of the memory pillar MP, surrounded by a layer from a lower end of the select gate line SGD3a to an upper end of the select gate line SGD3b), and this area is doped with boron.

A concentration of boron of an area in the memory pillar MP (the semiconductor layer 41) within the string unit SU0, in which the area is surrounded by the select gate lines SGD0a and SGD0b and the insulating layer 33 between the select gate lines SGD0a and SGD0b, is approximately equal to that of an area in the memory pillar MP (the semiconductor layer 41) within the string unit SU1, in which the area is surrounded by the select gate lines SGD1a and SGD1b and the insulating layer 33 between the select gate lines SGD1a and SGD1b. The same applies to a concentration of boron of an area in the memory pillar MP (the semiconductor layer 41) within the string unit SU2, in which the area is surrounded by the select gate lines SGD2a and SGD2b and the insulating layer 33 between the select gate lines SGD2a and SGD2b. The same applies to a concentration of boron of an area in the memory pillar MP (the semiconductor layer 41) within the string unit SU3, in which the area is surrounded by the select gate lines SGD3a and SGD3b and the insulating layer 33 between the select gate lines SGD3a and SGD3b.

As described above, in each string unit SU, each memory pillar MP has an area corresponding to the uppermost select gate line group SGDG, and this area is doped with boron. In other words, in the aforementioned area, the semiconductor layer 41 of the memory pillar MP (a channel area of the select transistor ST1) includes boron. The threshold voltage Vth of the select transistor ST1 varies depending on the concentration of an impurity in the channel area. In the case where the area is doped with boron as the impurity, the threshold voltage Vth of the select transistor ST1 become greater as the concentration of boron increases.

By the area being doped with boron as described above, in the string unit SU0, a threshold voltage Vth of the select transistor ST1a is greater than those of the select transistor ST1b, the select transistor ST1c, and the select transistor ST1d. In the string unit SU1, the threshold voltage Vth of the select transistor ST1b is greater than those of the select transistor ST1c and the select transistor ST1d. In the string unit SU2, the threshold voltage Vth of the select transistor ST1c is greater than that of the select transistor ST1d. In other words, in each string unit SU including the plurality of select gate line groups SGDG, the threshold value Vth of the select transistor ST1 corresponding to the uppermost select gate line group SGDG is greater than those of the select transistors ST1 corresponding to the select gate line groups SGDG lower than the uppermost select gate line group SGDG.

The threshold voltage Vth of the select transistor ST1a within the string unit SU0 is approximately equal to that of the select transistor ST1b within the string unit SU1, for example. The same applies to the threshold value Vth of the select transistor ST1c within the string unit SU2, and the threshold value Vth of the select transistor ST1d within the string unit SU3.

In the select gate line group SGDG1, the threshold voltage Vth of the select transistor ST1b within the string unit SU1 is greater than that of the select transistor SIM within the string unit SU0. In the select gate line group SGDG2, the threshold voltage Vth of the select transistor ST1c within the string unit SU2 is greater than those of the select transistor ST1c within the string unit SU0 and the select transistor ST1c within the string unit SU1. In the select gate line group SGDG3, the threshold voltage Vth of the select transistor ST1d within the string unit SU3 is greater than those of the select transistor ST1d within the string unit SU0, the select transistor ST1d within the string unit SU1, and the select transistor ST1d within the string unit SU2.

The example in FIG. 6 shows the threshold voltages Vth of the select transistors ST1a to ST1d, set by adjusting the concentration of boron to be doped. In the string unit SU0, the threshold voltage Vth of the select transistor ST1a is set to 20 V, and the threshold voltage Vth of each of the select transistors ST1b, ST1c, and Slid is set to 10 V. In the string unit SU1, the threshold voltage Vth of the select transistor ST1b is set to 20 V, and the threshold voltage Vth of each of the select transistors ST1c and Slid is set to 10 V. In the string unit SU2, the threshold voltage Vth of the select transistor ST1c is set to 20 V, and the threshold voltage Vth of the select transistor Slid is set to 10 V. In the string unit SU3, the threshold voltage Vth of the select transistor Slid is set to 20 V. The threshold voltage Vth of the select transistor ST1 in each string unit SU is not limited to those described above. Furthermore, a material to be doped as the impurity is not necessarily boron as long as the threshold voltages Vth of the select transistors ST1 are increased by doping with such a material as compared to those before doping.

### 1.1.6 Operation Principle of Selecting String Unit

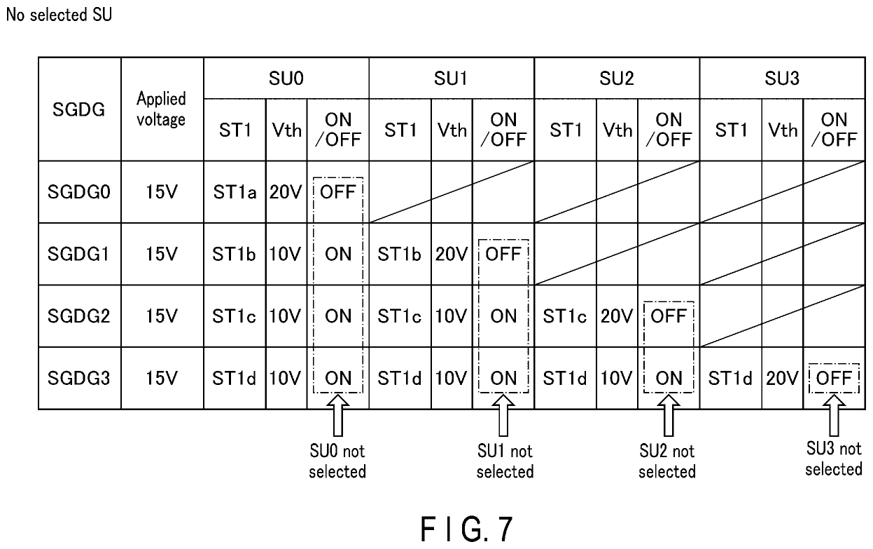

The operation principle of selecting a string unit SU will be described with reference to FIG. 7 to FIG. 11. The following will describe the case in which the value of the threshold voltage Vth shown in in FIG. 6 is set to the select transistor ST1 in each select gate line group SGDG within each string unit SU.

FIG. 7 is a diagram for illustrating the operation principle in the case in which none of the string units SU is selected in the semiconductor memory device 3.

In the example shown in FIG. 7, for example, the voltage of 15 V is applied to each of the select gate line groups SGDG0 to SGDG3 (the select gate lines SGD0a, SGD0b, SGD1a, SGD1b, SGD2a, SGD2b, SGD3a, and SGD3b). The voltage of 15 V is greater than the minimum threshold voltage (=10 V) and smaller than the maximum threshold voltage (=20 V) of the threshold voltages Vth of the select transistors ST1 set in each string unit SU. Meanwhile, the voltage applied to each of the select gate line groups SGDG0 to SGDG3 may be, for example, 0 V.

In the string unit SU0, the voltage (=15 V) applied to the select gate line group SGDG0 is smaller than the threshold voltage Vth (=20 V) of the select transistor ST1a corresponding to the select gate line group SGDG0, so that the select transistor ST1a is turned off. The voltage (=15 V) applied to the select gate line group SGDG1 is greater than the threshold voltage Vth (=10 V) of the select transistor ST1b corresponding to the select gate line group SGDG1, so that the select transistor ST1b is turned on. The voltage (=15 V) applied to the select gate line group SGDG2 is greater than the threshold voltage Vth (=10 V) of the select transistor ST1c corresponding to the select gate line group SGDG2, so that the select transistor ST1c is turned on. The voltage (=15 V) applied to the select gate line group SGDG3 is greater than the threshold voltage Vth (=10 V) of the select transistor Slid corresponding to the select gate line group SGDG3, so that the select transistor Slid is turned on. Since the select transistor ST1a is not turned on, the string unit SU0 is not selected.

In the string unit SU1, the voltage (=15 V) applied to the select gate line group SGDG1 is smaller than the threshold voltage Vth (=20 V) of the select transistor ST1b corresponding to the select gate line group SGDG1, so that the select transistor ST1b is turned off. The voltage (=15 V) applied to the select gate line group SGDG2 is greater than the threshold voltage Vth (=10 V) of the select transistor ST1c corresponding to the select gate line group SGDG2, so that the select transistor ST1c is turned on. The voltage (=15 V) applied to the select gate line group SGDG3 is greater than the threshold voltage Vth (=10 V) of the select transistor Slid corresponding to the select gate line group SGDG3, so that the select transistor Slid is turned on. Since the select transistor ST1b is not turned on, the string unit SU1 is not selected.

In the string unit SU2, the voltage (=15 V) applied to the select gate line group SGDG2 is smaller than the threshold voltage Vth (=20 V) of the select transistor ST1c corresponding to the select gate line group SGDG2, so that the select transistor ST1c is turned off. The voltage (=15 V) applied to the select gate line group SGDG3 is greater than the threshold voltage Vth (=10 V) of the select transistor Slid corresponding to the select gate line group SGDG3, so that the select transistor Slid is turned on. Since the select transistor ST1c is not turned on, the string unit SU2 is not selected.

In the string unit SU3, the voltage (=15 V) applied to the select gate line group SGDG3 is smaller than the threshold voltage Vth (=20 V) of the select transistor Slid corresponding to the select gate line group SGDG3, so that the select transistor Slid is turned off. Since the select transistor Slid is not turned on, the string unit SU3 is not selected.

By the operation described above, none of the string units SU is selected.

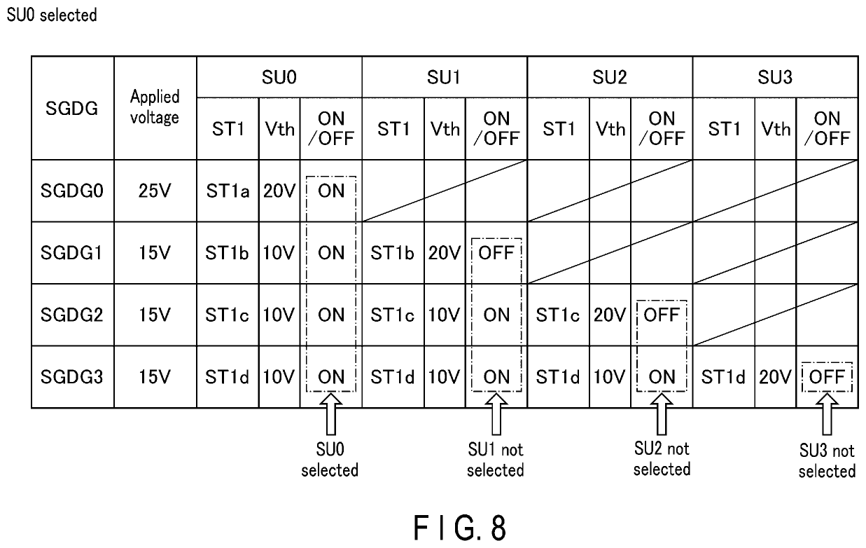

FIG. 8 is a diagram for illustrating the operation principle in the case in which the string unit SU0 is selected in the semiconductor memory device 3.

In the example shown in FIG. 8, the voltage of 25 V is applied to the select gate line group SGDG0 (the select gate lines SGD0a and SGD0b), for example. The voltage of 25 V is greater than the maximum threshold voltage (=20 V) of the threshold voltages Vth of the select transistors ST1 set in each string unit SU. For example, the voltage of 15 V is applied to each of the select gate line groups SGDG1 to SGDG3 (the select gate lines SGD1a, SGD1b, SGD2a, SGD2b, SGD3a, and SGD3b).

In the string unit SU0, the voltage (=25 V) applied to the select gate line group SGDG0 is greater than the threshold voltage Vth (=20 V) of the select transistor ST1a corresponding to the select gate line group SGDG0, so that the select transistor ST1a is turned on. The select transistor SIM corresponding to the select gate line group SGDG1, the select transistor ST1c corresponding to the select gate line group SGDG2, and the select transistor ST1d corresponding to the select gate line group SGDG3 are turned on as with the example shown in FIG. 7. As a result, the string unit SU0 is selected.

In the string unit SU1, the select transistor ST1b corresponding to the select gate line group SGDG1 is turned off as with the example shown in FIG. 7. The select transistor ST1c corresponding to the select gate line group SGDG2 and the select transistor ST1d corresponding to the select gate line group SGDG3 are turned on as with the example shown in FIG. 7. As a result, the string unit SU1 is not selected.

In the string unit SU2, the select transistor ST1c corresponding to the select gate line group SGDG2 is turned off as with the example shown in FIG. 7. The select transistor ST1d corresponding to the select gate line group SGDG3 is turned on as with the example shown in FIG. 7. As a result, the string unit SU2 is not selected.

In the string unit SU3, the select transistor ST1d corresponding to the select gate line group SGDG3 is turned off as with the example shown in FIG. 7. As a result, the string unit SU3 is not selected.

By the operation described above, the string unit SU0 is selected.

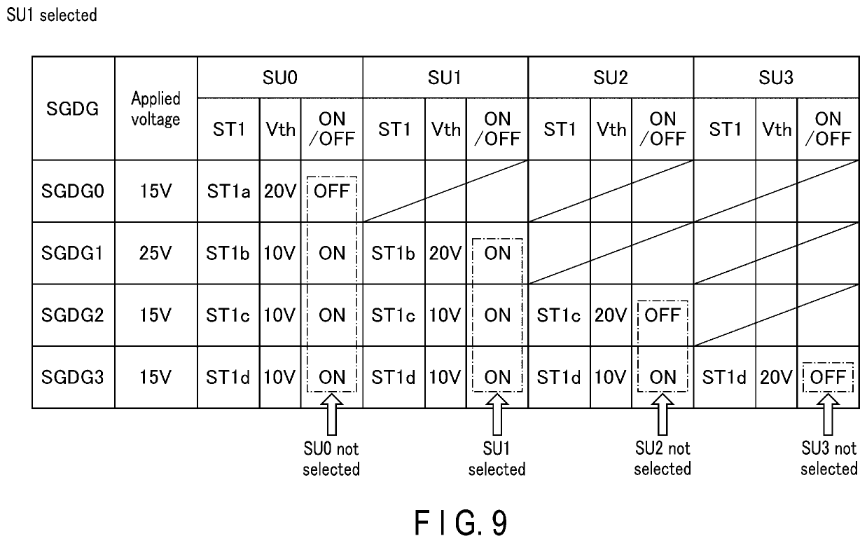

FIG. 9 is a diagram for illustrating the operation principle in the case in which the string unit SU1 is selected in the semiconductor memory device 3.

In the example shown in FIG. 9, the voltage of 25 V is applied to the select gate line group SGDG1 (the select gate lines SGD1a and SGD1b), for example. For example, the voltage of 15 V is applied to each of the select gate line groups SGDG0, SGDG2 and SGDG3 (the select gate lines SGD0a, SGD0b, SGD2a, SGD2b, SGD3a, and SGD3b).

In the string unit SU0, the select transistor ST1a corresponding to the select gate line group SGDG0 is turned off as with the example shown in FIG. 7. The voltage (=25 V) applied to the select gate line group SGDG1 is greater than the threshold voltage Vth (=10 V) of the select transistor ST1b corresponding to the select gate line group SGDG1, so that the select transistor ST1b is turned on. The select transistor ST1c corresponding to the select gate line group SGDG2 and the select transistor ST1d corresponding to the select gate line group SGDG3 are turned on as with the example shown in FIG. 7. As a result, the string unit SU0 is not selected.

In the string unit SU1, the voltage (=25 V) applied to the select gate line group SGDG1 is greater than the threshold voltage Vth (=20 V) of the select transistor ST1b corresponding to the select gate line group SGDG1, so that the select transistor ST1b is turned on. The select transistor ST1c corresponding to the select gate line group SGDG2 and the select transistor ST1d corresponding to the select gate line group SGDG3 are turned on as with the example shown in FIG. 7. As a result, the string unit SU1 is selected.

In the string unit SU2, the select transistor ST1c corresponding to the select gate line group SGDG2 is turned off as with the example shown in FIG. 7. The select transistor ST1d corresponding to the select gate line group SGDG3 is turned on as with the example shown in FIG. 7. As a result, the string unit SU2 is not selected.

In the string unit SU3, the select transistor ST1d corresponding to the select gate line group SGDG3 is turned off as with the example shown in FIG. 7. As a result, the string unit SU3 is not selected.

By the operation described above, the string unit SU1 is selected.

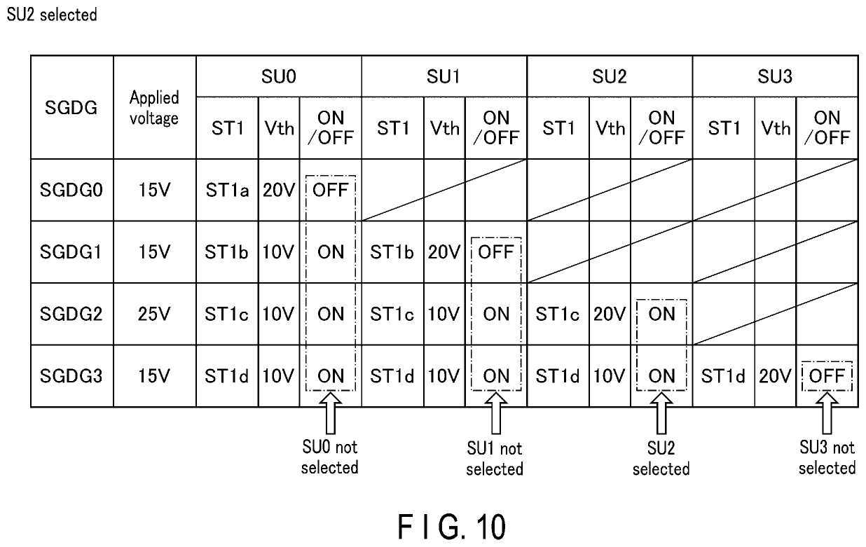

FIG. 10 is a diagram for illustrating the operation principle in the case in which the string unit SU2 is selected in the semiconductor memory device 3.

In the example shown in FIG. 10, the voltage of 25 V is applied to the select gate line group SGDG2 (the select gate lines SGD2a and SGD2b), for example. For example, the voltage of 15 V is applied to each of the select gate line groups SGDG0, SGDG1, and SGDG3 (the select gate lines SGD0a, SGD0b, SGD1a, SGD1b, SGD3a, and SGD3b).

In the string unit SU0, the select transistor ST1a corresponding to the select gate line group SGDG0 is turned off as with the example shown in FIG. 7. The select transistor SIM corresponding to the select gate line group SGDG1 and the select transistor ST1d corresponding to the select gate line group SGDG3 are turned on as with the example shown in FIG. 7. The voltage (=25 V) applied to the select gate line group SGDG2 is greater than the threshold voltage Vth (=10 V) of the select transistor ST1c corresponding to the select gate line group SGDG2, so that the select transistor ST1c is turned on. As a result, the string unit SU0 is not selected.

In the string unit SU1, the select transistor ST1b corresponding to the select gate line group SGDG1 is turned off as with the example shown in FIG. 7. The voltage (=25 V) applied to the select gate line group SGDG2 is greater than the threshold voltage Vth (=10 V) of the select transistor ST1c corresponding to the select gate line group SGDG2, so that the select transistor ST1c is turned on. The select transistor ST1d corresponding to the select gate line group SGDG3 is turned on as with the example shown in FIG. 7. As a result, the string unit SU1 is not selected.

In the string unit SU2, the voltage (=25 V) applied to the select gate line group SGDG2 is greater than the threshold voltage Vth (=20 V) of the select transistor ST1c corresponding to the select gate line group SGDG2, so that the select transistor ST1c is turned on. The select transistor ST1d corresponding to the select gate line group SGDG3 is turned on as with the example shown in FIG. 7. As a result, the string unit SU2 is selected.

In the string unit SU3, the select transistor ST1d corresponding to the select gate line group SGDG3 is turned off as with the example shown in FIG. 7. As a result, the string unit SU3 is not selected.

By the operation described above, the string unit SU2 is selected.

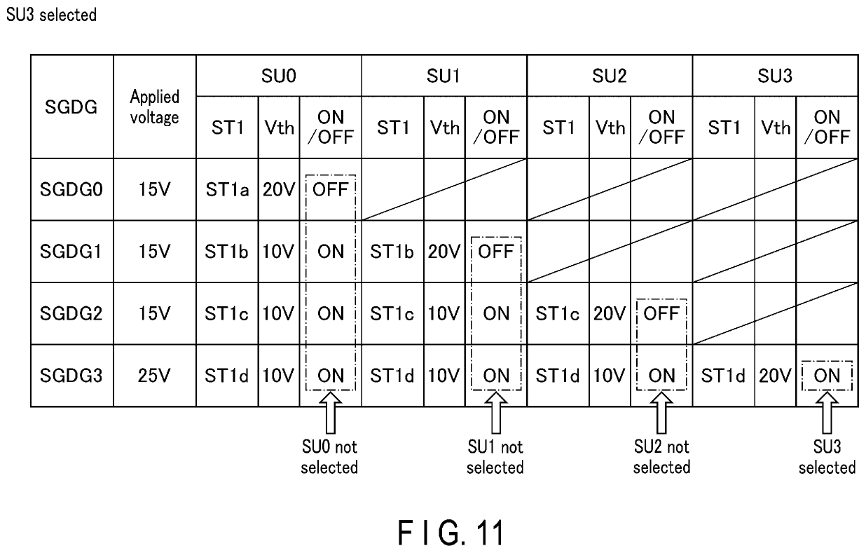

FIG. 11 is a diagram for illustrating the operation principle in the case in which the string unit SU3 is selected in the semiconductor memory device 3.

In the example shown in FIG. 11, the voltage of 25 V is applied to the select gate line group SGDG3 (the select gate lines SGD3a and SGD3b), for example. For example, the voltage of 15 V is applied to each of the select gate line groups SGDG0 to SGDG2 (the select gate lines SGD0a, SGD0b, SGD1a, SGD1b, SGD2a, and SGD2b).

In the string unit SU0, the select transistor ST1a corresponding to the select gate line group SGDG0 is turned off as with the example shown in FIG. 7. The select transistor SIM corresponding to the select gate line group SGDG1 and the select transistor ST1c corresponding to the select gate line group SGDG2 are turned on as with the example shown in FIG. 7. The voltage (=25 V) applied to the select gate line group SGDG3 is greater than the threshold voltage Vth (=10 V) of the select transistor Slid corresponding to the select gate line group SGDG3, so that the select transistor Slid is turned on. As a result, the string unit SU0 is not selected.

In the string unit SU1, the select transistor ST1b corresponding to the select gate line group SGDG1 is turned off as with the example shown in FIG. 7. The select transistor ST1c corresponding to the select gate line group SGDG2 is turned on as with the example shown in FIG. 7. The voltage (=25 V) applied to the select gate line group SGDG3 is greater than the threshold voltage Vth (=10 V) of the select transistor Slid corresponding to the select gate line group SGDG3, so that the select transistor Slid is turned on. As a result, the string unit SU1 is not selected.

In the string unit SU2, the select transistor ST1c corresponding to the select gate line group SGDG2 is turned off as with the example shown in FIG. 7. The voltage (=25 V) applied to the select gate line group SGDG3 is greater than the threshold voltage Vth (=10 V) of the select transistor Slid corresponding to the select gate line group SGDG3, so that the select transistor Slid is turned on. As a result, the string unit SU2 is not selected.

In the string unit SU3, the voltage (=25 V) applied to the select gate line group SGDG3 is greater than the threshold voltage Vth (=20 V) of the select transistor Slid corresponding to the select gate line group SGDG3, so that the select transistor Slid is turned on. As a result, the string unit SU3 is selected.

By the operation described above, the string unit SU3 is selected.

### 1.2 Method of Manufacturing Semiconductor Memory Device

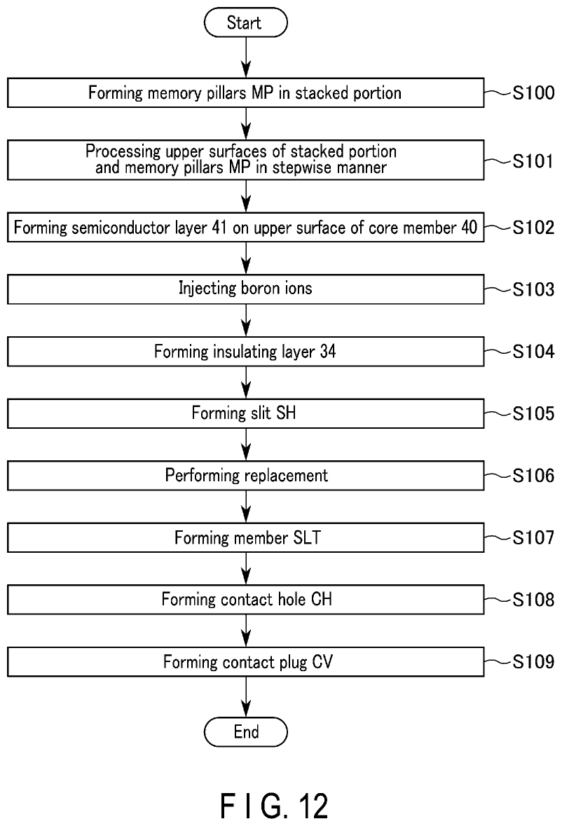

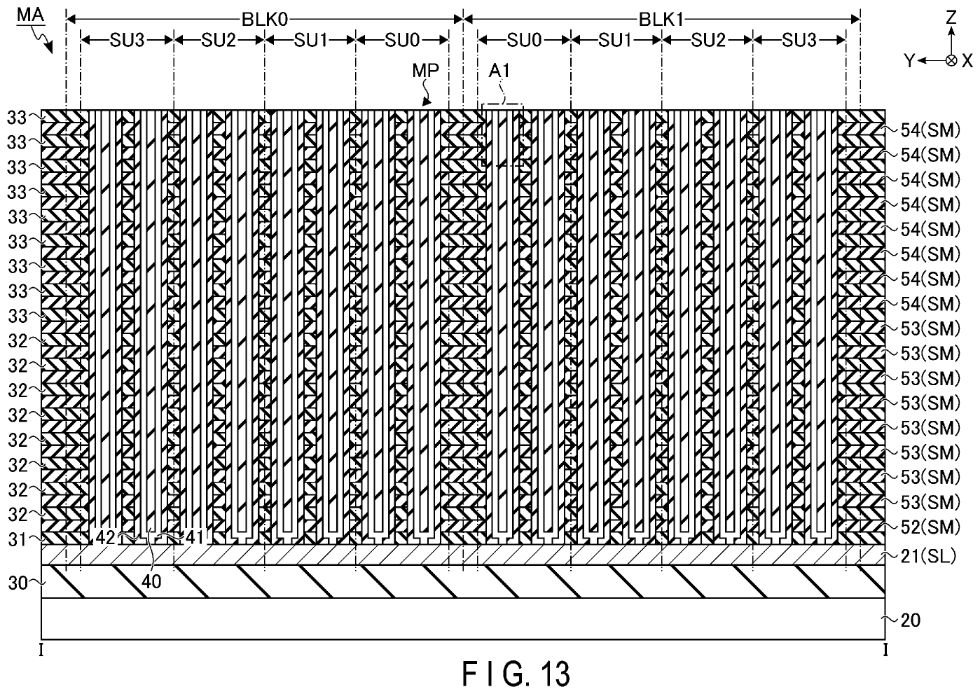

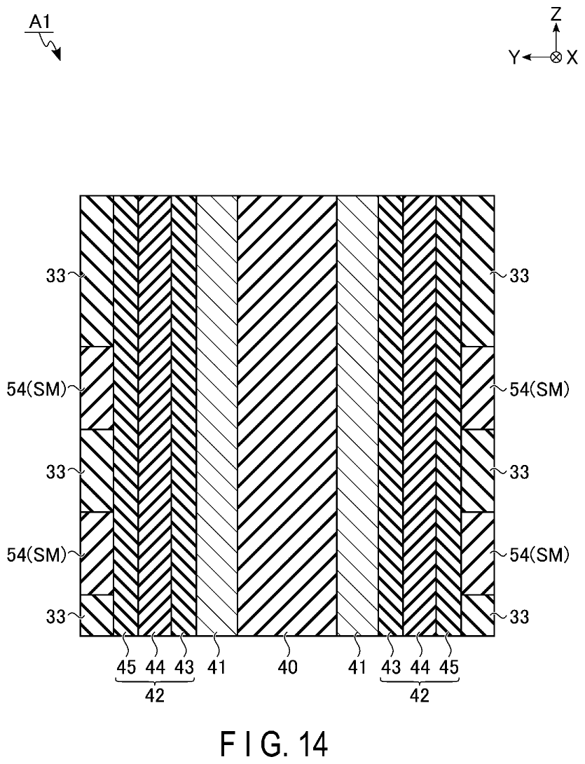

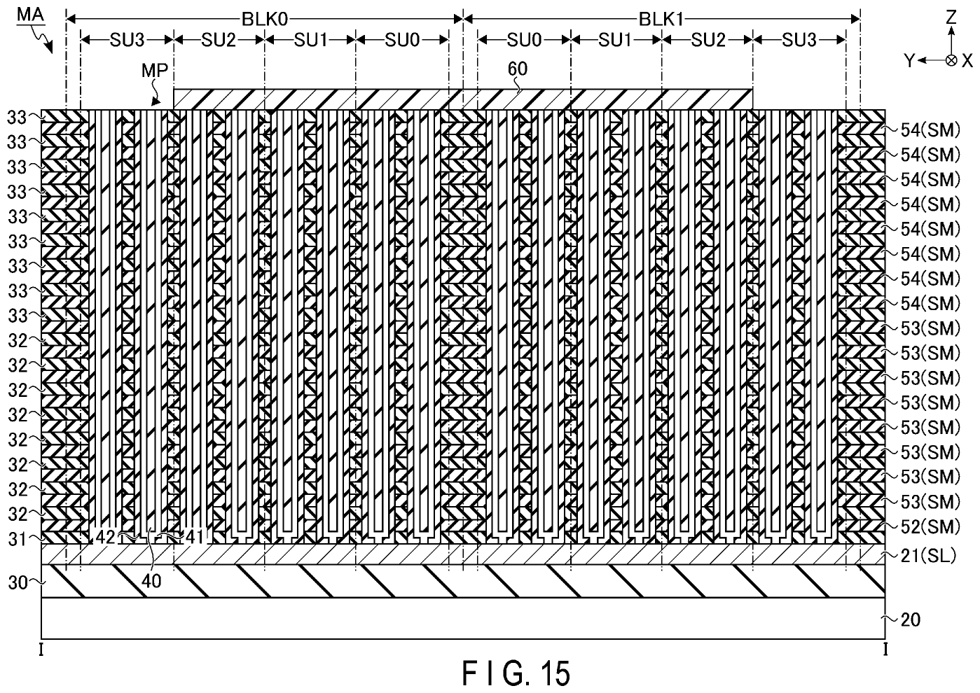

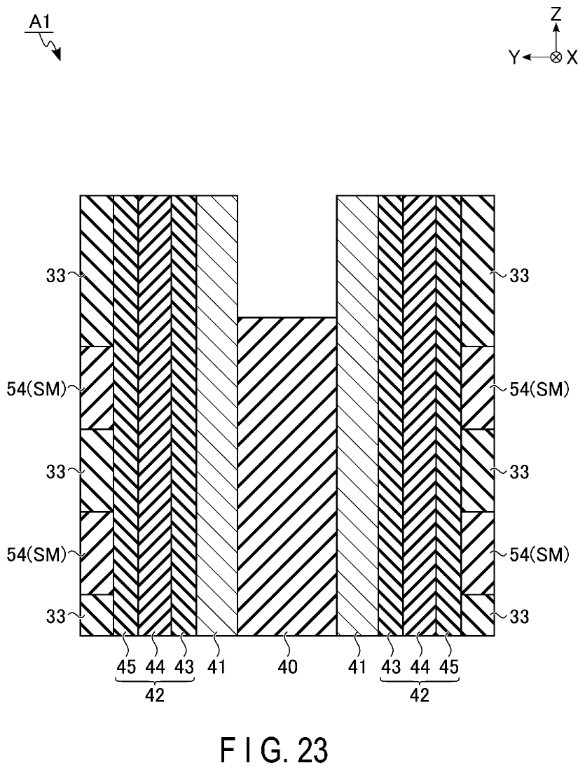

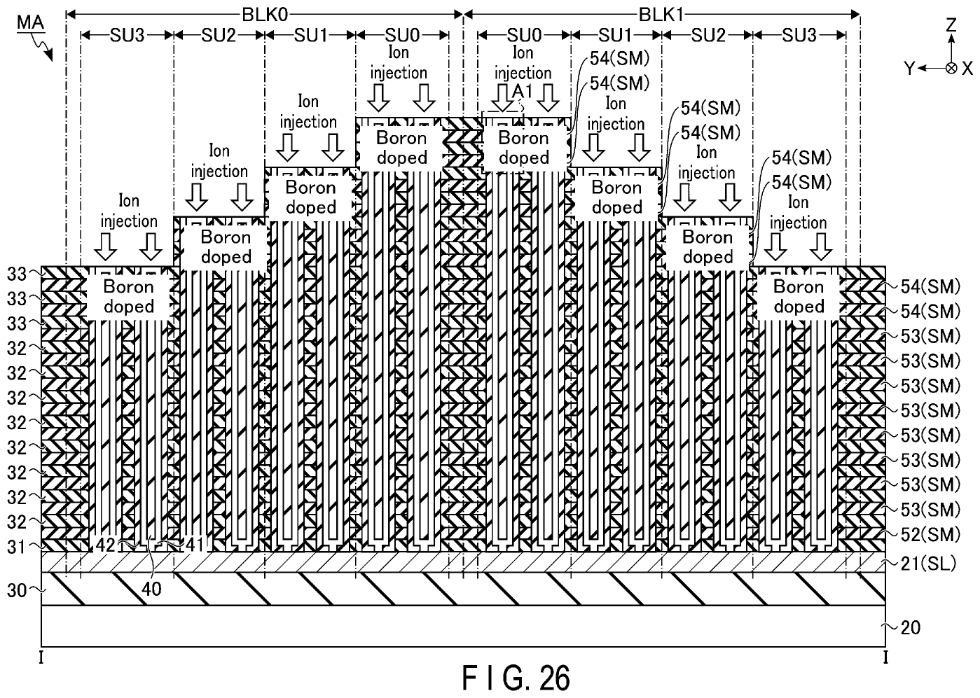

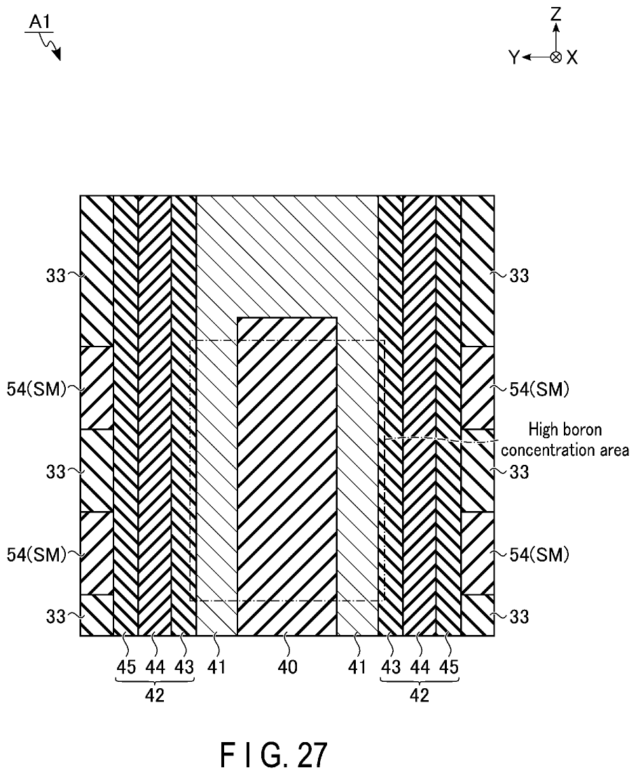

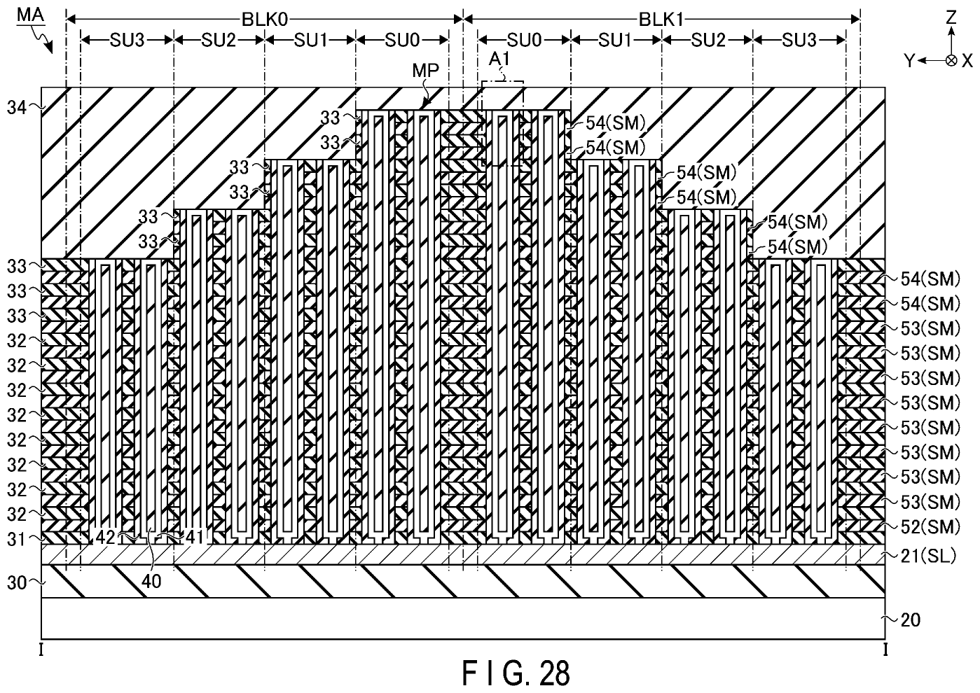

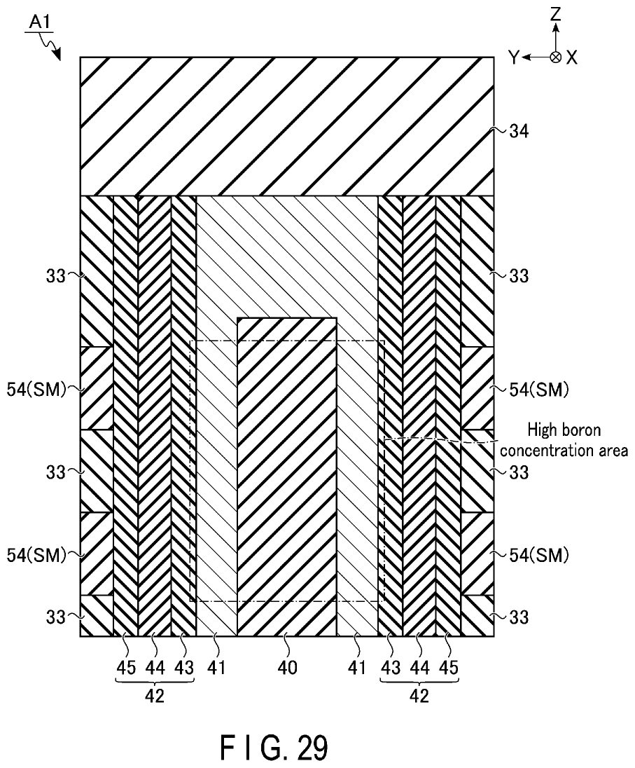

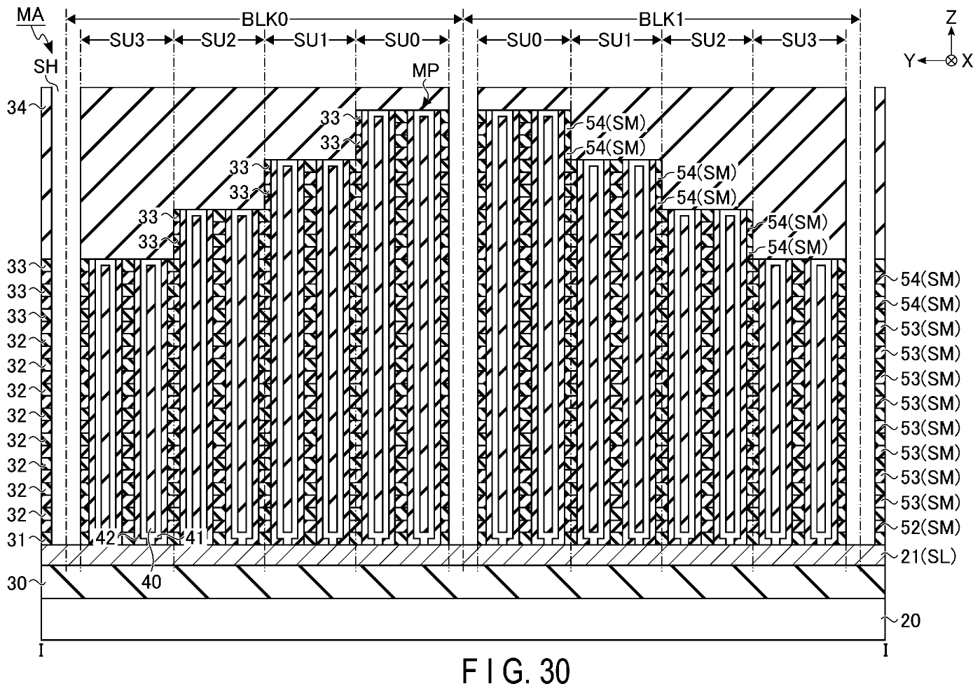

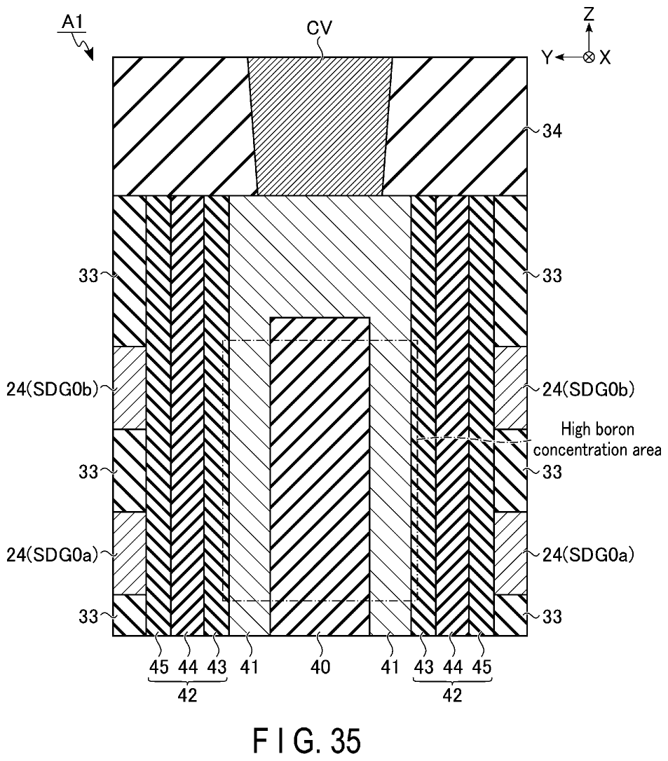

The method of manufacturing the semiconductor device 3 will be described with reference to FIG. 12 to FIG. 35. The following will describe a process of manufacturing the memory area MA of the semiconductor memory device 3 after formation of the memory pillars MP. FIG. 12 is a flowchart showing an example of a method of manufacturing the memory area MA of the semiconductor memory device 3. FIG. 13, FIG. 15 to FIG. 22, FIG. 26, FIG. 28, and FIG. 30 to FIG. 34 are each a cross-sectional view showing an example of a cross-sectional structure during a process of manufacturing the memory area MA of the semiconductor memory device 3. FIG. 14, FIG. 23 to FIG. 25, FIG. 27, FIG. 29, and FIG. 35 are each a partially enlarged view of the cross-sectional structure during the process of manufacturing the memory area MA of the semiconductor memory device 3.

As shown in FIG. 12, steps S100 to S109 are sequentially executed during the process of manufacturing the memory area MA of the semiconductor memory device 3. The following will describe an example of the process of manufacturing the memory area MA of the semiconductor memory device 3 by suitably referring to FIG. 12.

As a method of forming the interconnect layers 22 to 24, there exists a method of forming the interconnect layers 22 to 24 by forming a structure corresponding to the interconnect layers 22 to 24 using sacrificial layers and thereafter replacing the sacrificial layers with a conductive material (hereinafter referred to as “replacement”). In the present embodiment, a sacrificial layer 52 corresponds to the interconnect layer 22, a sacrificial layer 53 corresponds to the interconnect layer 23, and a sacrificial layer 54 corresponds to the interconnect layer 24. The sacrificial layers 52 to 54 are formed of an insulating material and include, for example, a silicon nitride.

As shown in FIG. 13, the pillars MP are formed in the stacked portion (S100). For example, after the stacked portion in which the plurality of sacrificial layers 52 to 54 and the plurality of insulating layers 32 and 33 are alternatively stacked in the Z direction is formed above the semiconductor substrate 20, the memory pillars MP each extending in the Z direction and penetrating an area corresponding to each string unit SU of the stacked portion are formed. Hereinafter, eight sacrificial layers 54 will also be referred to as a first sacrificial layer, a second sacrificial layer, a third sacrificial layer, a fourth sacrificial layer, a fifth sacrificial layer, a sixth sacrificial layer, a seventh sacrificial layer, and an eighth sacrificial layer sequentially from the uppermost sacrificial layer 54. FIG. 14 is an enlarged view of an area A1 in layers higher than the third sacrificial layer 54 of one memory pillar MP in an area corresponding to the string unit SU0 in the block BLK1 shown in FIG. 13. As shown in FIG. 14, the semiconductor layer 41 covers the periphery of the core member 40. The upper surface of the core member 40 is exposed. The stacked film 42 includes the tunnel insulating film 43, the insulating film 44, and the block insulating film 45. The tunnel insulating film 43 covers the periphery of the semiconductor layer 41. The insulating film 44 covers the periphery of the tunnel insulating film 43. The block insulating film 45 covers the periphery of the insulating film 44. The plurality of insulating layers 33, the first sacrificial layer 54, and the second sacrificial layer 54 cover the periphery of the block insulating film 45.

Next, the upper surfaces of the stacked portion and the memory pillars MP are processed in a stepwise manner (S101). Specifically, first, as shown in FIG. 15, a resist mask 60 is formed on the memory pillar MP and the uppermost insulating layer 33 by, for example, photolithography, etc. The resist mask 60 is formed in such a manner as to cover an area from an end portion of the string unit SU3 side in an area corresponding to the string unit SU2 in the block BLK0 to an end portion of the string unit SU3 side in an area corresponding to the string unit SU2 in the block BLK1, for example. In other words, in the upper surfaces of the memory pillars MP and the uppermost insulating layer 33, an area corresponding to the string unit SU3 is exposed.

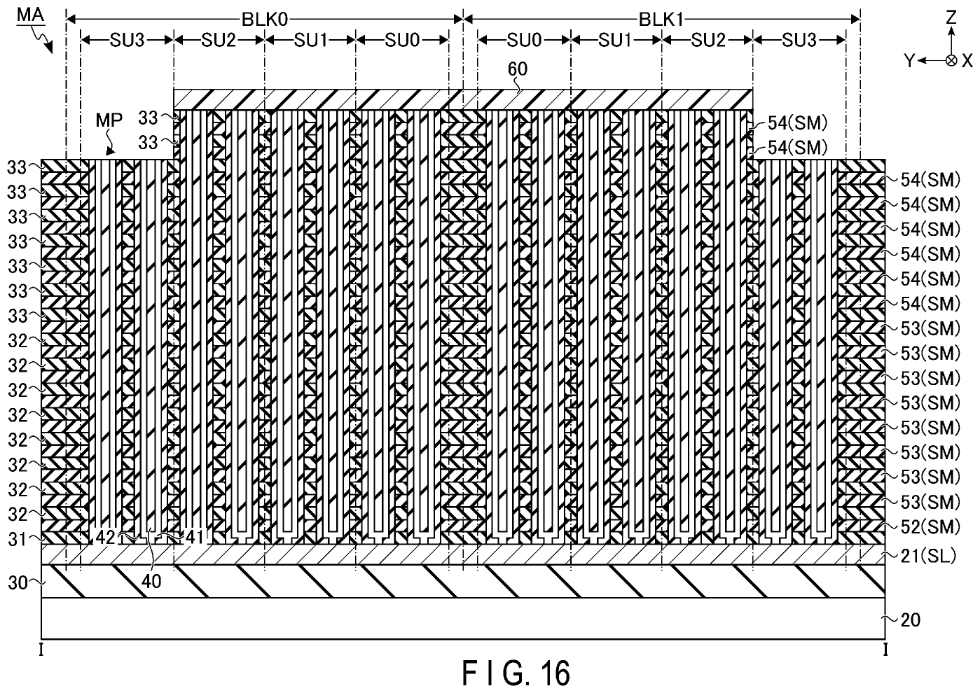

Next, as shown in FIG. 16, for example, the memory pillars MP, the insulating layers 33, and the sacrificial layer 54 in an area corresponding to the string unit SU3 are processed through anisotropic etching by reactive ion etching (RIE). Specifically, the first and second sacrificial layers 54, two insulating layers 33, and the memory pillars MP in the string unit SU3 are removed down to a lower end of the second sacrificial layer 54.

For example, the first and second sacrificial layers, two insulating layers, and the memory pillars MP in the string unit SU3 are processed in such a manner that a height from an upper end of the area corresponding to the string unit SU3 of the stacked portion to the third sacrificial layer 54 and a height from the aforementioned upper end to the fourth sacrificial layer 54 become approximately equal to a height from an upper end of the area corresponding to the string unit SU2 of the stacked portion to the first sacrificial layer 54 and a height from the aforementioned upper end to the second sacrificial layer 54, respectively. At this time, the amount of etching is set such that the third sacrificial layer 54 remains unexposed in the area corresponding to the string unit SU3. In this manner, the layers higher than the insulating layer 33 provided on the third sacrificial layer 54 are partially removed in the area corresponding to the string unit SU3.

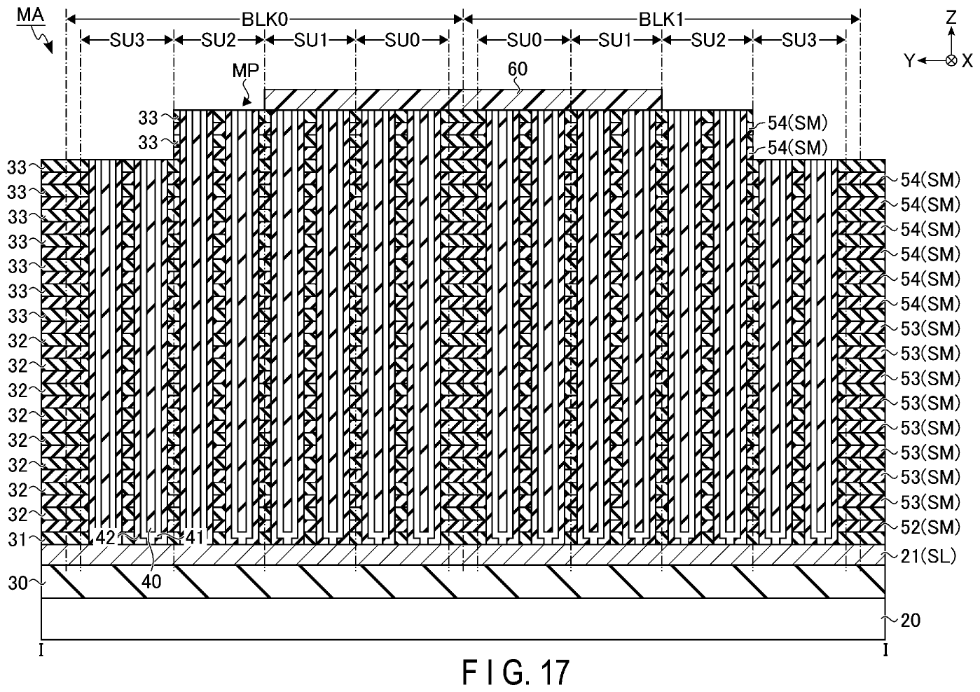

Next, as shown in FIG. 17, the resist mask 60 is partially removed through, for example, asking. In the resist mask 60, for example, a portion corresponding to the string unit SU2 in the block BLK0 and a portion corresponding to the string unit SU2 in the block BLK1 are removed. In other words, in the upper surfaces of the memory pillars MP and the uppermost insulating layer 33, a portion corresponding to each of the string units SU2 and SU3 is exposed.

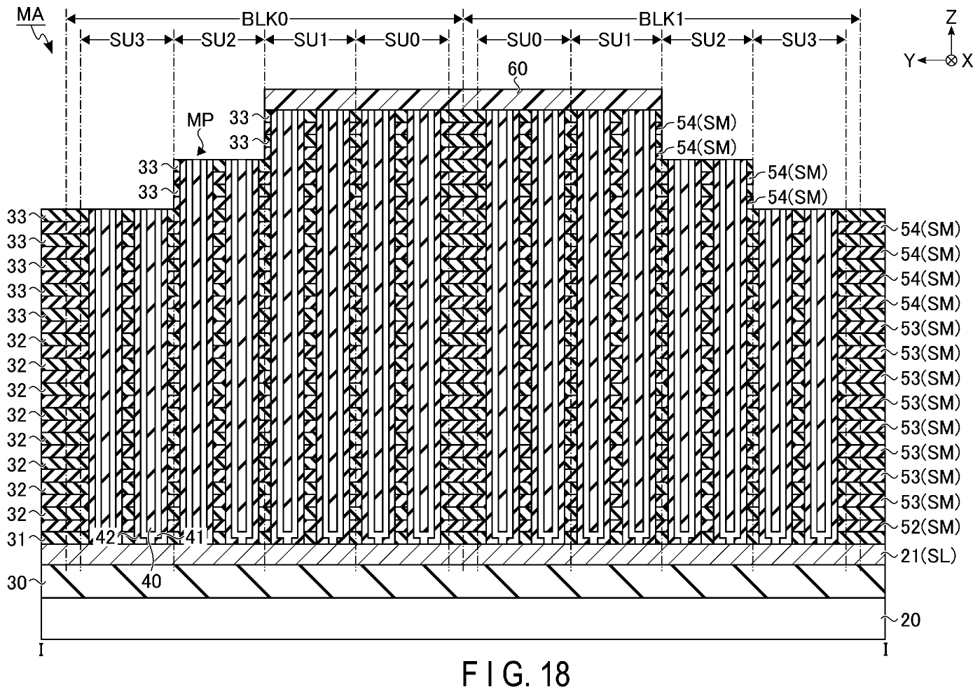

Next, as shown in FIG. 18, for example, the memory pillars MP, the insulating layers 33, and the sacrificial layer 54 in an area corresponding to each of the string units SU2 and SU3 are processed through anisotropic etching by RIE. Specifically, the third and fourth sacrificial layers 54, two insulating layers 33, and the memory pillars MP in the string unit SU3 are removed down to a lower end of the fourth sacrificial layer 54. The first and second sacrificial layers 54, two insulating layers 33, and the memory pillars MP in the string unit SU2 are removed down to the lower end of the second sacrificial layer 54.

For example, the third and fourth sacrificial layers, two insulating layers, and the memory pillars MP in the string unit SU3 are processed in such a manner that a height from the upper end of the area corresponding to the string unit SU3 of the stacked portion to the fifth sacrificial layer 54 and a height from the aforementioned upper end to the sixth sacrificial layer 54 become approximately equal to a height from an upper end of the area corresponding to the string unit SU1 of the stacked portion to the first sacrificial layer 54 and a height from the aforementioned upper end to the second sacrificial layer 54, respectively. The first and second sacrificial layers, two insulating layers, and the memory pillars MP in the string unit SU2 are processed in such a manner that a height from the upper end of the area corresponding to the string unit SU2 of the stacked portion to the third sacrificial layer 54 and a height from the aforementioned upper end to the fourth sacrificial layer 54 become approximately equal to the height from the upper end of the area corresponding to the string unit SU1 of the stacked portion to the first sacrificial layer 54 and the height from the aforementioned upper end to the second sacrificial layer 54, respectively. At this time, the amount of etching is set such that the third sacrificial layer 54 remains unexposed in the area corresponding to the string unit SU2, and the fifth sacrificial layer 54 remains unexposed in the area corresponding to the string unit SU3. In this manner, the layers higher than the insulating layer 33 provided on the third sacrificial layer 54 are partially removed in the area corresponding to the string unit SU2. The layers higher than the insulating layer 33 provided on the fifth sacrificial layer 54 are partially removed in the area corresponding to the string unit SU3.

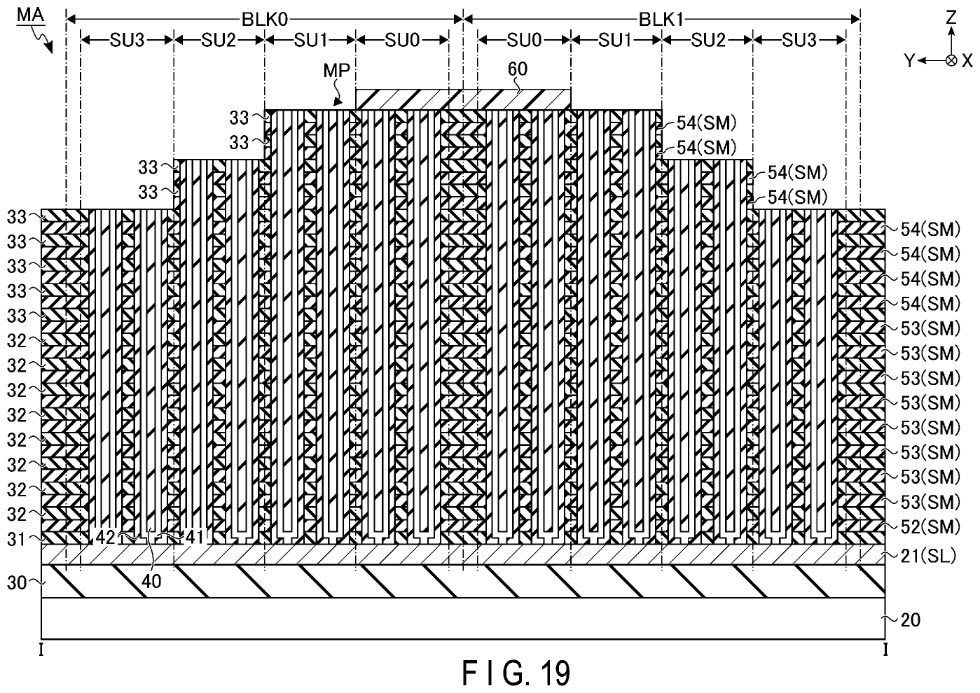

Next, as shown in FIG. 19, the resist mask 60 is partially removed through, for example, asking. In the resist mask 60, for example, a portion corresponding to the string unit SU1 in the block BLK0 and a portion corresponding to the string unit SU1 in the block BLK1 are removed. In other words, in the upper surfaces of the memory pillars MP and the uppermost insulating layer 33, a portion corresponding to each of the string units SU1 to SU3 is exposed.

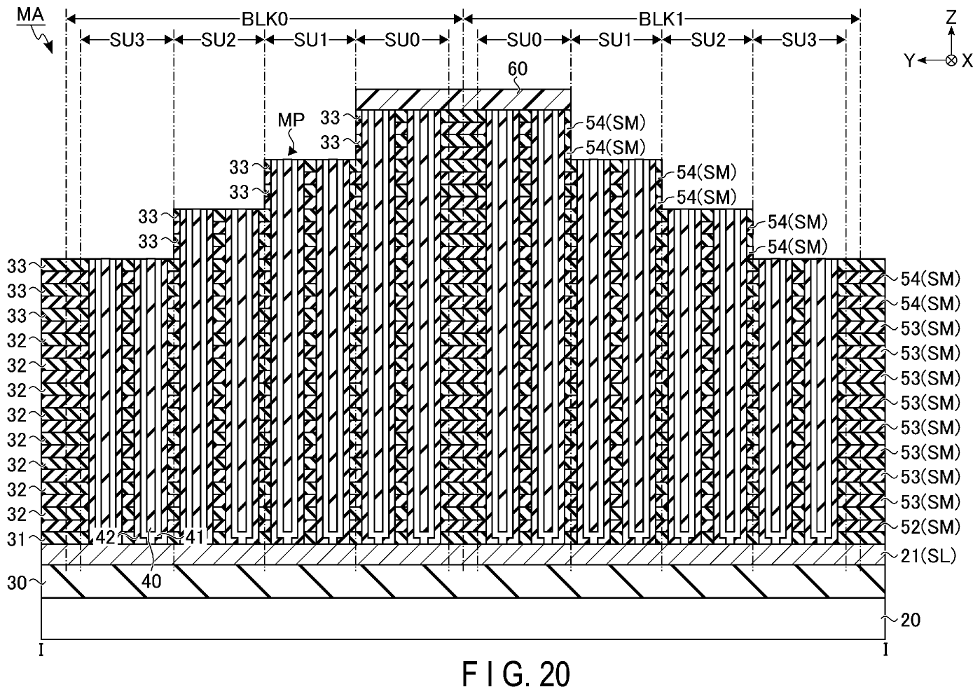

Next, as shown in FIG. 20, for example, the memory pillars MP, the insulating layers 33, and the sacrificial layer 54 in an area corresponding to each of the string units SU1 to SU3 are processed through anisotropic etching by RIE, for example. Specifically, the fifth and sixth sacrificial layers 54, two insulating layers 33, and the memory pillars MP in the string unit SU3 are removed down to a lower end of the sixth sacrificial layer 54. The third and fourth sacrificial layers 54, two insulating layers 33, and the memory pillars MP in the string unit SU2 are removed down to the lower end of the fourth sacrificial layer 54. The first and second sacrificial layers 54, two insulating layers 33, and the memory pillars MP in the string unit SU1 are removed down to the lower end of the second sacrificial layer 54.

For example, the fifth and sixth sacrificial layers, two insulating layers, and the memory pillars MP in the string unit SU3 are processed in such a manner that a height from the upper end of the area corresponding to the string unit SU3 of the stacked portion to the seventh sacrificial layer 54 and a height from the aforementioned upper end to the eighth sacrificial layer 54 become approximately equal to a height from an upper end of the area corresponding to the string unit SU0 of the stacked portion to the first sacrificial layer 54 and a height from the aforementioned upper end to the second sacrificial layer 54, respectively. The third and fourth sacrificial layers, two insulating layers, and the memory pillars MP in the string unit SU2 are processed in such a manner that a height from the upper end of the area corresponding to the string unit SU2 of the stacked portion to the fifth sacrificial layer 54 and a height from the aforementioned upper end to the sixth sacrificial layer 54 become approximately equal to the height from the upper end of the area corresponding to the string unit SU0 of the stacked portion to the first sacrificial layer 54 and the height from the aforementioned upper end to the second sacrificial layer 54, respectively. The first and second sacrificial layers, two insulating layers, and the memory pillars MP in the string unit SU1 are processed in such a manner that a height from the upper end of the area corresponding to the string unit SU1 of the stacked portion to the third sacrificial layer 54 and a height from the aforementioned upper end to the fourth sacrificial layer 54 become approximately equal to the height from the upper end of the area corresponding to the string unit SU0 of the stacked portion to the first sacrificial layer 54 and the height from the aforementioned upper end to the second sacrificial layer 54, respectively. At this time, the amount of etching is set such that the third sacrificial layer 54 remains unexposed in the area corresponding to the string unit SU1, the fifth sacrificial layer 54 remains unexposed in the area corresponding to the string unit SU2, and the seventh sacrificial layer 54 remains unexposed in the area corresponding to the string unit SU3. In this manner, the layers higher than the insulating layer 33 provided on the third sacrificial layer 54 are partially removed in the area corresponding to the string unit SU1. The layers higher than the insulating layer 33 provided on the fifth sacrificial layer 54 are partially removed in the area corresponding to the string unit SU2. The layers higher than the insulating layer 33 provided on the seventh sacrificial layer 54 are partially removed in the area corresponding to the string unit SU3.

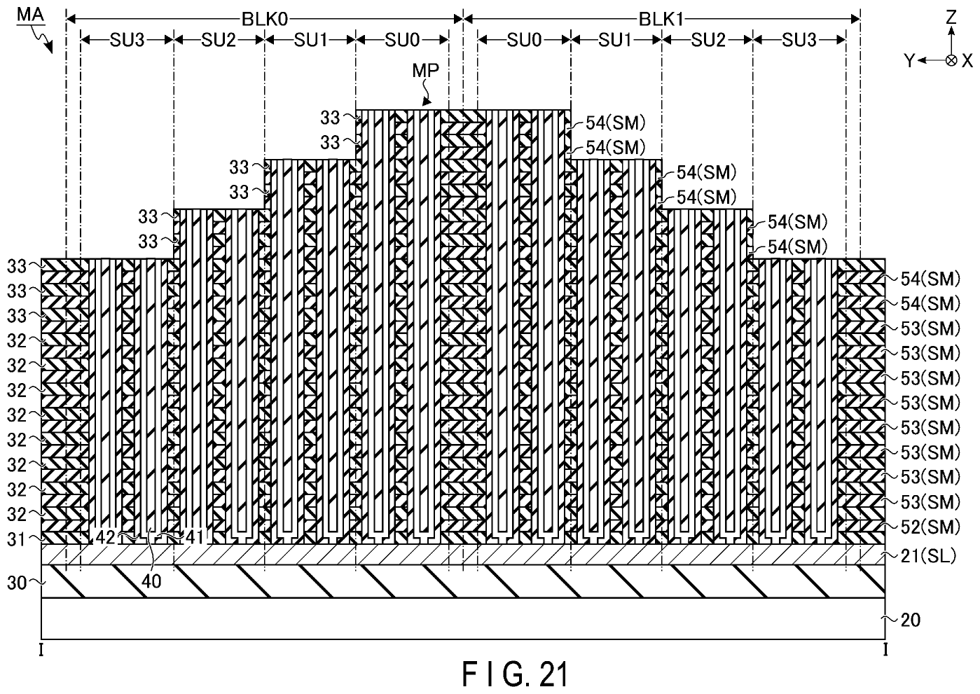

Next, as shown in FIG. 21, the resist mask 60 is removed.

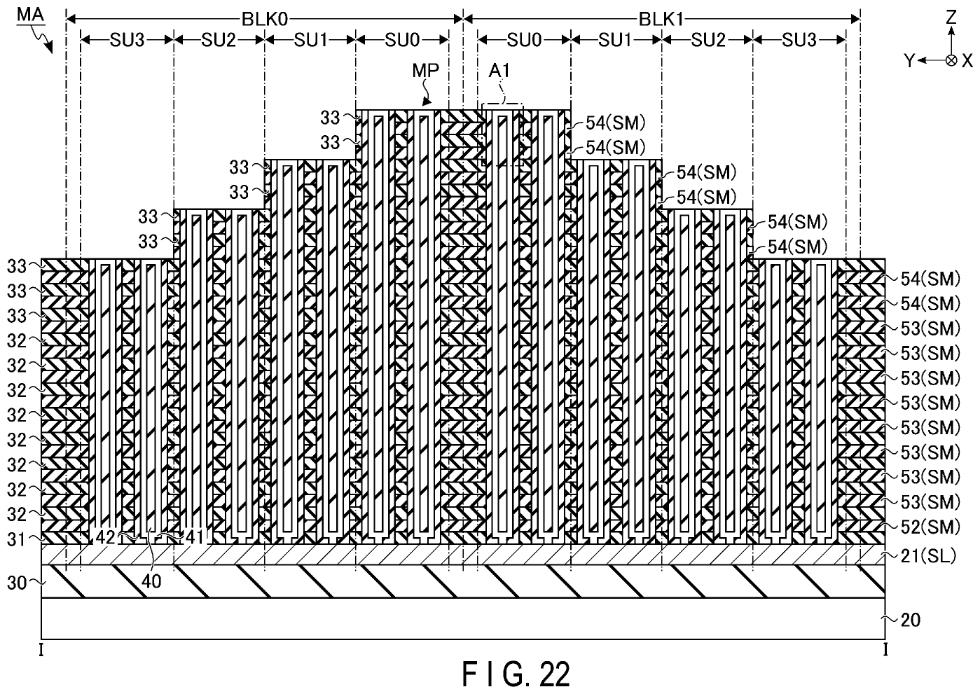

Next, as shown in FIG. 22, the semiconductor layer 41 is formed on the upper surface of each core member 40 of each memory pillar MP (S102). FIG. 23 to FIG. 25 are each an enlarged view of the area A1 in layers higher than the third sacrificial layer 54 of one memory pillar MP in the area corresponding to the string unit SU0 in the block BLK1 shown in FIG. 22.

Specifically, first, as shown in FIG. 23, the core member 40 is partially removed through, for example, etch-back. In this manner, the upper end of the core member 40 is located below upper ends of the semiconductor layer 41, the stacked film 42, and the insulating layer 33.

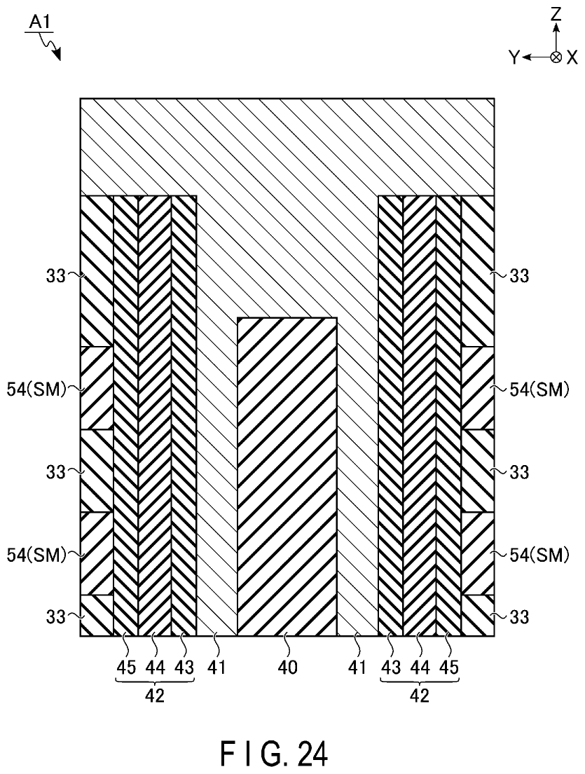

Next, as shown in FIG. 24, for example, amorphous silicon is formed on the core member 40, the semiconductor layer 41, the stacked film 42, and the insulating layer 33. In this manner, the amorphous silicon is integrated with the semiconductor layer 41. As a result, the upper surfaces of the core member 40, the stacked film 42, and the insulating layer 33 are covered with the semiconductor layer 41.

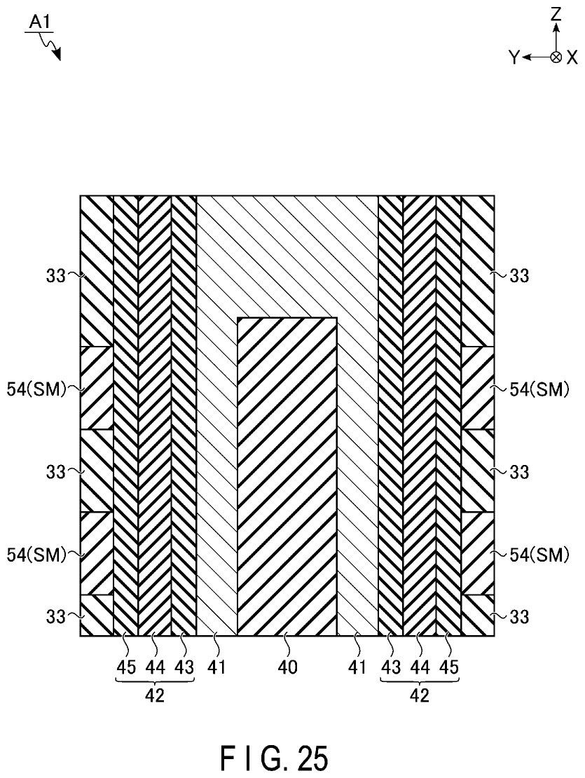

Next, as shown in FIG. 25, the semiconductor layer 41 is partially removed through, for example, etch-back. In this manner, the upper surfaces of the stacked film 42 and the insulating layer 33 are exposed.

Next, as shown in FIG. 26, for example, in an area corresponding to each string unit SU, boron ions are injected into each memory pillar MP (S103). Specifically, in the area corresponding to each string unit SU, boron ions are injected into an area surrounded by the sacrificial layers 54 positioned first and second from the upper end of the memory pillar MP, and the insulating layer 33 between these sacrificial layers 54. The depth of injection is controlled using the acceleration voltage. In an area corresponding to each string units SU, a depth to the sacrificial layer 54 positioned first from the upper end of the memory pillar MP and a depth to the sacrificial layer 54 positioned second from the upper end of the memory pillar MP are approximately equal to each other. Accordingly, in the present embodiment, one ion injection using the acceleration voltage of one type enables boron ions to be injected into each memory pillar MP to the depth of a lower end of the sacrificial layer 54 positioned second from the upper end of the memory pillar MP in the area corresponding to each string unit SU. In this manner, an area with a higher concentration of boron (hereinafter referred to as a “high boron concentration area”) than that of the remaining areas in the semiconductor layer 41 can be formed in an area surrounded by the sacrificial layers 54 positioned first and second from the upper end of each memory pillar MP and the insulating layer 33 between these sacrificial layers 54 (the semiconductor layer 41 of the memory pillar MP surrounded by the layers ranging from the lower end of the sacrificial layer 54 positioned second from the upper end of the memory pillar MP to the upper end of the sacrificial layer 54 one layer above the aforementioned sacrificial layer 54). FIG. 27 is an enlarged view of the area A1 in layers higher than the third sacrificial layer 54 of one memory pillar MP in an area corresponding to the string unit SU0 in the block BLK1 shown in FIG. 26. As shown in FIG. 27, a high boron concentration area is formed in the semiconductor layer 41 of each memory pillar MP surrounded by the layers ranging from the lower end of the second sacrificial layer 54 to the upper end of the first sacrificial layer 54.

Next, as shown in FIG. 28, the insulating layer 34 is formed on each memory pillar MP and the uppermost insulating layer 33 (S104). FIG. 29 is an enlarged view of the area A1 in layers higher than the third sacrificial layer 54 of one memory pillar MP in an area corresponding to the string unit SU0 of the block BLK1 shown in FIG. 28. As shown in FIG. 29, the insulating layers 34 are formed on the memory pillar MP and the uppermost insulating layer 33.

Next, as shown in FIG. 30, slits SH each penetrating the stacked portion in the Z direction are formed (S105). The slits SH penetrate, for example, each of the insulating layers 31 to 34 and sacrificial layers 52 to 54. The bottom surface of each slit SH reaches the interconnect layer 21.

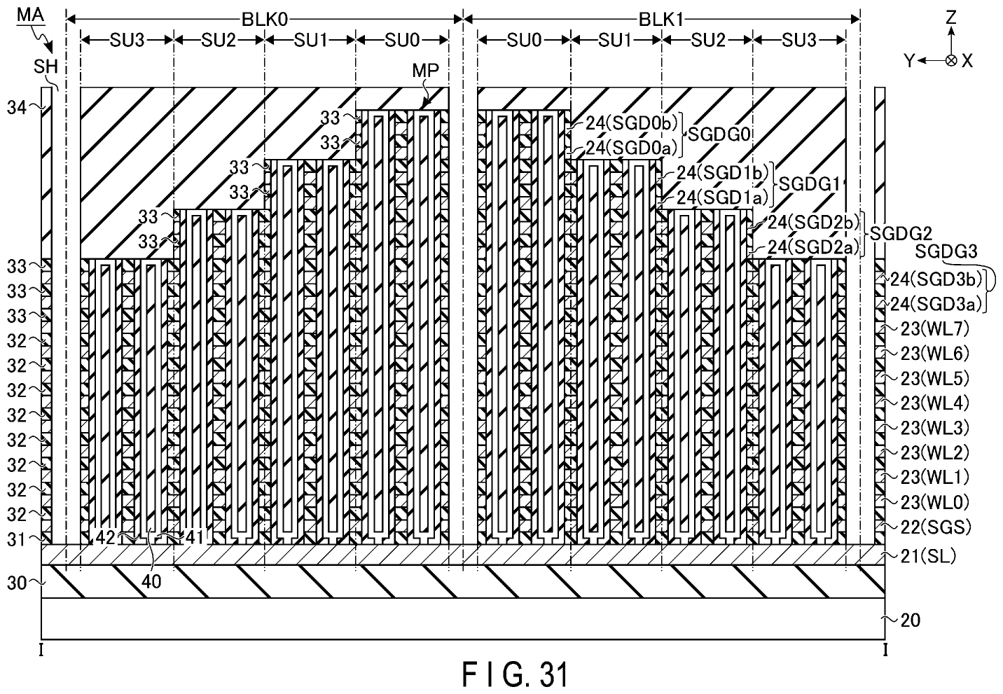

Next, as shown in FIG. 31, the replacement is performed (S106). Specifically, first, the sacrificial layers 52 to 54 are removed through, for example, isotropic etching by wet etching. Next, the interconnect layers 22 to 24 are formed in an area from which the sacrificial layers 52 to 54 are removed.

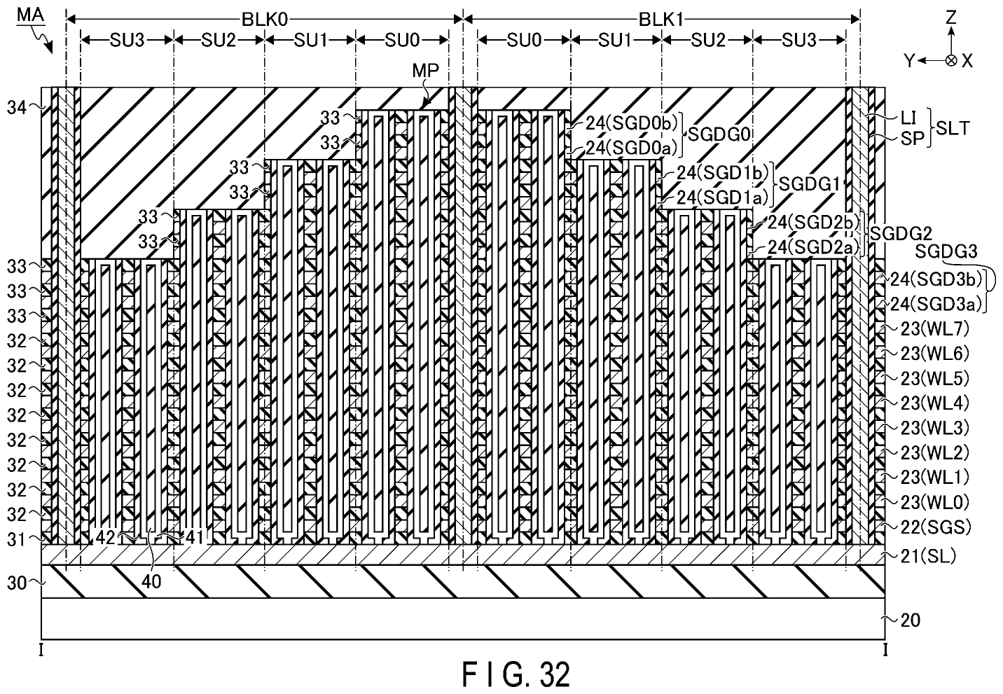

Next, as shown in FIG. 32, the member SLT is formed (S107). Specifically, first, the spacer SP is formed on the side surface of each slit SH. Next, the contact plug LI is embedded in each SH.

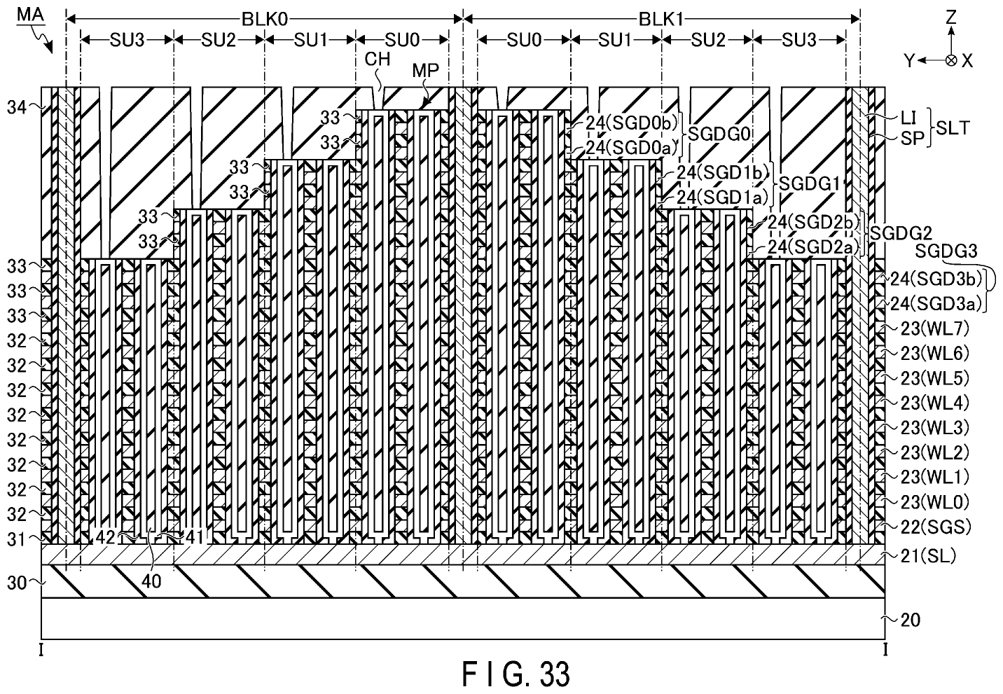

Next, as shown in FIG. 33, contact holes CH are formed (S108). The contact holes CH penetrate, for example, the insulating layer 34. The bottom surface of each contact hole CH reaches the semiconductor layer 41 of each memory pillar MP.

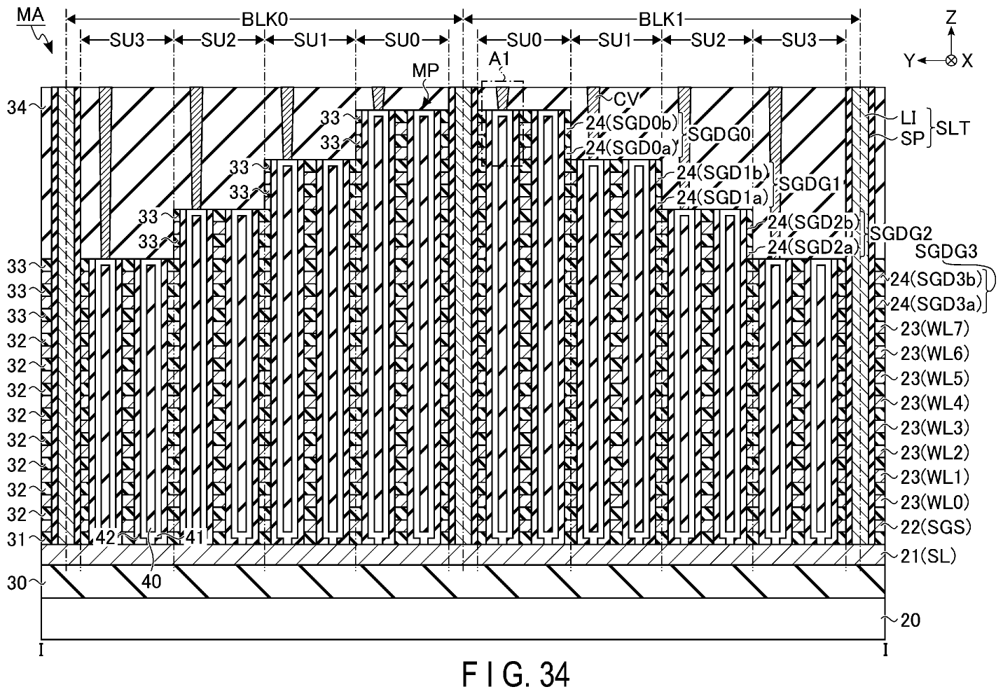

Next, as shown in FIG. 34, the contact plugs CV are formed (S109). Specifically, the contact plugs CV are respectively embedded in the contact holes CH. FIG. 35 is an enlarged view of the area A1 in layers higher than the interconnect layer 24 obtained by replacing the third sacrificial layer in one memory pillar MP in an area corresponding to the string unit SU0 in the block BLK1 shown in FIG. 34. As shown in FIG. 35, the contact plug CV is formed on the semiconductor layer 41 of the memory pillar MP.

Through the manufacturing process described above, the memory area MA of the semiconductor memory device 3 is formed. The manufacturing process described above is merely an example and is not limited thereto. For example, another step may be inserted between the respective manufacturing steps or a part of the steps may be omitted or integrated. Furthermore, the respective manufacturing steps may be interchanged where possible. For example, after injection of boron ions, the semiconductor layer 41 may be formed on the upper surface of the core member 40 of each memory pillar MP.

### 1.3 Advantageous Effect

According to the present embodiment, the degree of cell integration can be improved. The advantageous effects will be described below.

As a structure in which the select gate line SGD is divided for each string unit SU, there exists a structure in which the select gate line SGD is physically divided for each string unit SU by providing dummy memory pillars MP (hereinafter referred to as “dummy pillars”) in the memory area MA and further providing members (hereinafter referred to as “members SHE”) for dividing the select gate line SGD in such a manner as to overlap the dummy pillars. This structure is provided with the dummy pillars and thus there is a possibility that the degree of cell integration becomes lower.

On the other hand, in the present embodiment, the string unit SU3 includes the select gate line group SGDG3. The string unit SU2 includes the select gate line group SGDG3 and the select gate line group SGDG2 arranged above the select gate line group SGDG3. The string unit SU1 includes the select gate line groups SGDG2 and SGDG3, and the select gate line group SGDG1 arranged above the select gate line group SGDG2. The string unit SU0 includes the select gate line groups SGDG1 to SGDG3, and the select gate line group SGDG0 arranged above the select gate line group SGDG1.

In the string unit SU3, the area corresponding to the select gate line group SGDG3 of the memory pillar MP is doped with boron. In the string unit SU2, the area corresponding to the select gate line group SGDG2 of the memory pillar MP is doped with boron. In the string unit SU1, the area corresponding to the select gate line group SGDG1 of the memory pillar MP is doped with boron. In the string unit SU0, the area corresponding to the select gate line group SGDG0 of the memory pillar MP is doped with boron. The select transistor ST1 in the area doped with boron is greater in threshold voltage than the select transistor ST1 in the area not doped with boron. Therefore, one string unit SU can be selected by controlling the voltage to be applied to each select gate line group SGDG. This enables the select gate line SGD to be electrically divided for each string unit SU. Therefore, the dummy pillars and the members SHE may not be provided in the memory area MA. Thus, according to the present embodiment, the degree of cell integration can be improved.

In the present embodiment, the members SHE is not provided, so that the interconnect layer 24 is not divided by them. Therefore, as shown in FIG. 4, among the plurality of members SLT, the interconnect layer 22 (the select gate line SGS), the interconnect layers 23 (the word lines WL0 to WL7), and the interconnect layers 24 (the select gate lines SGD3a and SGD3b) are approximately equal to each other in length in the Y direction. That is, among the plurality of members SLT, the interconnect layer 23 (the word line WL7) and the interconnect layer 24 (the select gate lines SGD3a and SGD3b) of the select gate line group SGDG3 arranged between the aforementioned interconnect layer 23 and the select gate line groups SGDG0 to SGDG2 (the select gate lines SGD0a, SGD0b, SGD1a, SGD1b, SGD2a, and SGD2b) in the Z direction are approximately equal to each other in length in the Y direction.

Furthermore, with the aforementioned structure in which the select gate line SGD is physically divided for each string unit SU, the members SHE are formed after formation of the slits SH. The bottom surface of each slit SH reaches the interconnect layer 21. Therefore, as the number of stacked layers for the memory cell array 10 increases, the slits SH increase in aspect ratio. This causes a possibility that an incline will occur in the stacked interconnects SI. In the case where such an incline occurs, displacement may occur in positioning of the members SHE and the dummy pillars at the time of formation of the members SHE.

On the other hand, in the present embodiment, before formation of the slits SH, boron ions are injected into each memory pillar MP to the depth of the lower end of the sacrificial layer 54 positioned second from the upper end of the memory pillar MP in each string unit SU. Thus, according to the present embodiment, the structure in which the select gate line SGD is divided for each string unit SU can avoid an influence of an occurrence of an incline. Furthermore, the members SHE may not be provided in the memory area MA. Thus, according to the present embodiment, the degree of difficulty in process can be reduced.

Furthermore, in a case of electrically dividing the select gate line SGD for each string unit SU by controlling an applied voltage according to a threshold voltage set in the select transistor ST1, in the case where heights of the memory pillars MP are equal among the string units SU, ion injection into each memory pillar MP is executed independently by changing the acceleration voltage for each string unit SU. In this manner, a desired area with a different depth from the upper end of each memory pillar MP for each string unit SU can be doped with boron.

On the other hand, in the present embodiment, in each string unit SU, the depth to the sacrificial layer 54 positioned first from the upper end of the memory pillar MP and the depth to the sacrificial layer 54 positioned second from the upper end of the memory pillar MP are approximately equal to each other. Accordingly, one ion injection using the acceleration voltage of one type enables boron ions to be injected collectively into a desired area in the memory pillars MP to the depth of the lower end of the sacrificial layer 54 positioned second from the upper end of each memory pillar MP. Thus, according to the present embodiment, the process can be simplified.

### 2. Modification, etc.

As described above, a semiconductor memory device according to an embodiment includes: stacked interconnects (SI) including a first interconnect layer (SGD3) and a second interconnect layer (SGD2), the first interconnect layer (SGD3) including a first area (SU3) and a second area (SU2) arranged in a first direction (Y), the second interconnect layer (SGD2) being arranged above the first interconnect layer in a second direction (Z) intersecting the first direction, the second interconnect layer not including the first area and including the second area; a first memory pillar (MP of SU3) arranged in the first area (SU3) and passing through the first interconnect layer (SGD3) in the second direction (Z); and a second memory pillar (MP of SU2) arranged in the second area (SU2) and passing through the first interconnect layer (SGD3) and the second interconnect layer (SGD2) in the second direction (Z).

The embodiments are not limited to the above-described aspects, but can be modified in various ways.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
stacked interconnects including a first interconnect layer and a second interconnect layer, the first interconnect layer including a first area and a second area arranged in a first direction, the second interconnect layer being arranged above the first interconnect layer in a second direction intersecting the first direction, the second interconnect layer not including the first area and including the second area;
a first memory pillar arranged in the first area and passing through the first interconnect layer in the second direction; and
a second memory pillar arranged in the second area and passing through the first interconnect layer and the second interconnect layer in the second direction.

2. The device according to claim 1, wherein
the first memory pillar includes a first semiconductor layer passing through the first interconnect layer in the second direction,
the second memory pillar includes a second semiconductor layer passing through the first interconnect layer and the second interconnect layer in the second direction, and
an upper end of the second semiconductor layer is located above an upper end of the first semiconductor layer in the second direction.

3. The device according to claim 2, wherein
in the second direction,
the upper end of the first semiconductor layer is located between the first interconnect layer and the second interconnect layer, and
the upper end of the second semiconductor layer is located above the second interconnect layer.

4. The device according to claim 1, wherein
the first interconnect layer is an interconnect layer positioned first from an upper end of the first memory pillar, and
the second interconnect layer is an interconnect layer positioned first from an upper end of the second memory pillar.

5. The device according to claim 1, wherein in the second direction, a height from an upper end of the first memory pillar to the first interconnect layer is approximately equal to a height from an upper end of the second memory pillar to the second interconnect layer.

6. The device according to claim 1, wherein
a first transistor is formed in a portion in which the second memory pillar intersects the first interconnect layer,
a second transistor is formed in a portion in which the second memory pillar intersects the second interconnect layer,
a third transistor is formed in a portion in which the first memory pillar intersects the first interconnect layer, and
a first threshold voltage of the first transistor is smaller than a second threshold voltage of the second transistor and is smaller than a third threshold voltage of the third transistor.

7. The device according to claim 6, wherein the second threshold voltage is approximately equal to the third threshold voltage.

8. The device according to claim 6, wherein in a case where a first voltage greater than the first threshold voltage and smaller than the third threshold voltage is applied to the first interconnect layer, and a second voltage greater than the second threshold voltage is applied to the second interconnect layer, the second area is selected and the first area is not selected.

9. The device according to claim 6, wherein the first transistor, the second transistor, and the third transistor are select transistors.

10. The device according to claim 1, wherein
the first memory pillar includes a first semiconductor layer passing through the first interconnect layer in the second direction,
the second memory pillar includes a second semiconductor layer passing through the first interconnect layer and the second interconnect layer in the second direction, and
a third area surrounded by the first interconnect layer of the first semiconductor layer and a fourth area surrounded by the second interconnect layer of the second semiconductor layer include an impurity.

11. The device according to claim 10, wherein a concentration of the impurity in the third area is approximately equal to a concentration of the impurity in the fourth area.

12. The device according to claim 10, wherein a concentration of the impurity in the fourth area is greater than a concentration of the impurity in a fifth area surrounded by the first interconnect layer of the second semiconductor layer.

13. The device according to claim 10, wherein the impurity includes boron.

14. The device according to claim 1, further comprising:
a first plug arranged in the first area and provided on the first memory pillar; and
a second plug arranged in the second area and provided on the second memory pillar,
wherein in the second direction, a length of the second plug is different from a length of the first plug.

15. The device according to claim 1, further comprising a plurality of first members spaced apart from each other in the first direction with the stacked interconnects interposed therebetween, extending in the second direction and a third direction intersecting the first direction and the second direction, and dividing the stacked interconnects in the first direction, wherein
the stacked interconnects further include a third interconnect layer arranged below the first interconnect layer in the second direction, the third interconnect layer being passed through by the first memory pillar and the second memory pillar and having an intersecting portion with the first memory pillar and an intersecting portion with the second memory pillar, the intersecting portions being respectively provided with memory cell transistors,
select transistors are respectively formed in a portion in which the first memory pillar intersects the first interconnect layer and portions in which the second memory pillar intersects the first interconnect layer and the second interconnect layer, and
the third interconnect layer and the first interconnect layer are approximately equal to each other in length in the first direction between the plurality of first members.

16. The device according to claim 15, further comprising:
a first plug arranged in the first area and provided on the first memory pillar;
a second plug arranged in the second area and provided on the second memory pillar; and
a fourth interconnect layer arranged above the stacked interconnects and electrically coupled to the first memory pillar and the second memory pillar via the first plug and the second plug.

17. A semiconductor memory device comprising:
stacked interconnects including a first interconnect layer and a second interconnect layer, the first interconnect layer including a first area and a second area arranged in a first direction, the second interconnect layer being spaced apart from the first interconnect layer in a second direction intersecting the first direction, the second interconnect layer including the second area;
a plurality of first members spaced apart from each other in the first direction with the stacked interconnects interposed therebetween, extending in the second direction and a third direction intersecting the first direction and the second direction, and dividing the stacked interconnects in the first direction;
a first semiconductor layer arranged in the first area and passing through the first interconnect layer in the second direction; and
a second semiconductor layer arranged in the second area, having an upper end located above an upper end of the first semiconductor layer in the second direction, and passing through the first interconnect layer and the second interconnect layer in the second direction.

18. The device according to claim 17, wherein the second interconnect layer is arranged above the first interconnect layer in the second direction.

19. The device according to claim 18, wherein
the stacked interconnects further include a third interconnect layer arranged below the first interconnect layer in the second direction, the third interconnect layer being passed through by the first semiconductor layer and the second semiconductor layer and having an intersecting portion with the first semiconductor layer and an intersecting portion with the second semiconductor layer, the intersecting portions being respectively provided with memory cell transistors,
select transistors are respectively formed in a portion in which the first semiconductor layer intersects the first interconnect layer and portions in which the second semiconductor layer intersects the first interconnect layer and the second interconnect layer, and
the third interconnect layer and the first interconnect layer are approximately equal to each other in length in the first direction between the plurality of first members.

20. A semiconductor memory device comprising:
a first bit line;
a source line;
first to n-th (where n is an integer equal to or greater than 2) memory strings each including a plurality of memory cell transistors coupled in series, the first to n-th memory strings each being coupled between the first bit line and the source line;
a first word line; and
first to n-th gate lines; wherein
among the first to n-th memory strings, gates of corresponding memory cell transistors of the plurality of memory transistors each are coupled to the first word line,
the first memory string includes a first transistor between the first bit line and the plurality of memory cell transistors coupled in series, a drain of the first transistor being coupled to the first bit line, and a source of the first transistor being coupled to one end of the plurality of memory cell transistors coupled in series,
the n-th memory string includes first to n-th transistors coupled in series between the first bit line and the plurality of memory cell transistors coupled in series, a drain of the n-th transistor of the first to n-th transistors being coupled to the first bit line, and a source of the first transistor of the first to n-th transistors being coupled to one end of the plurality of memory cell transistors coupled in series,
gates of the first to n-th transistors in the n-th memory string are respectively coupled to the first to n-th gate lines, and a gate of the first transistor in the first memory string is coupled to the first gate line together with a gate of the first transistor in the n-th memory string, and
of the first to n-th transistors in the n-th memory string, the n-th transistor has a threshold voltage greater than a transistor except for the n-th transistor, and the first transistor in the first memory string has a threshold voltage greater than the first transistor in the n-th memory string.
